(19) United States
(12) Patent Application Publication
(10) Pub. No.: US 2018/0182977 A1
(43) Pub. Date: Jun. 28, 2018

(54) Light-Emitting Element, Light-Emitting Device, Electronic Device, Display Device, and Lighting Device

(71) Applicant: Semiconductor Energy Laboratory Co., Ltd., Kanagawa-ken (JP)

(72) Inventors: Tomoya Hirose, Atsugi (JP); Satoshi Seo, Sagamihara (JP); Tetsuo Tsutsui, Kasuga (JP)

(73) Assignee: Semiconductor Energy Laboratory Co., Ltd., Kanagawa-ken (JP)

(21) Appl. No.: 15/847,065

(22) Filed: Dec. 19, 2017

(30) Foreign Application Priority Data
Dec. 23, 2016 (JP) 2016-250253

(51) Int. Cl. H01L 51/00

(52) U.S. Cl. CPC H01L 51/0072; H01L 51/5012; H01L 51/0077

(57) ABSTRACT

A novel light-emitting element is provided. A light-emitting element with favorable emission efficiency is provided. A light-emitting element with favorable color purity is provided. The light-emitting element includes an anode, a cathode, and a layer including a light-emitting substance between the anode and the cathode. The layer including a light-emitting substance includes a light-emitting layer and an electron-transport layer. The light-emitting layer and the electron-transport layer are in contact with each other. The electron-transport layer is between the light-emitting layer and the cathode. The light-emitting layer includes a metal-halide perovskite material represented by a general formula (SA)MX₃, a general formula (LA)₂(SA)ₙ₋₁MₙX₃ₙ₊₁, or a general formula (PA)(SA)ₙ₋₁MₙX₃ₙ₊₁. The electron-transport layer includes a 1,10-phenanthroline derivative including a 1,10-phenanthroline skeleton having a substituent at one of 2- and 9-positions or substituents at both of the 2- and 9-positions.

### BACKGROUND OF THE INVENTION

### 1. Field of the Invention

One embodiment of the present invention relates to a light-emitting element, a display module, a lighting module, a display device, a light-emitting device, an electronic device, and a lighting device. Note that one embodiment of the present invention is not limited to the above technical field. The technical field of one embodiment of the invention disclosed in this specification and the like relates to an object, a method, or a manufacturing method. Furthermore, one embodiment of the present invention relates to a process, a machine, manufacture, or a composition of matter. Specifically, examples of the technical field of one embodiment of the present invention disclosed in this specification include a semiconductor device, a display device, a liquid crystal display device, a light-emitting device, a lighting device, a power storage device, a storage device, an imaging device, a method for driving any of them, and a method for manufacturing any of them.

### 2. Description of the Related Art

With the development of the display technology, the required level of performance is increasing day by day. The sRGB standard and the NTSC standard are conventionally well-known indicators for showing the reproducible color gamut of a display. Moreover, the BT.2020 standard, which covers a wider color gamut, has been proposed recently.

The BT.2020 standard can express almost all object colors; however, it is difficult under the present conditions to achieve it simply by using a broad emission spectrum of an organic compound as it is. Therefore, an attempt to meet the BT.2020 standard by increasing the color purity with the use of a cavity structure or the like has been made.

As another approach for meeting the BT.2020 standard, a material that originally has a narrow half width of an emission spectrum is used. Specifically, a quantum dot (QD), which is a tiny particle of several nanometers of a compound semiconductor, attracts attention as a substance for high color purity because a QD has discrete electron states and the discreteness limits the phase relaxation, narrowing the emission spectrum. The QD is expected as a light-emitting material which achieves the chromaticity of the BT.2020 standard.

A QD is made up of approximately 1×10³ to 1×10⁶ atoms and confines electrons, holes, or excitons, which produces discrete energy states and causes an energy shift depending on the size of QD. This means that QDs made of the same substance emit light with different wavelengths depending on their size; thus, the wavelength of light can be easily adjusted by changing the size of a QD.

In addition, a QD is said to have a theoretical internal quantum efficiency of approximately 100%, which far exceeds that of a fluorescent organic compound (25%) and is comparable to that of a phosphorescent organic compound.

However, if the particle size varies, the half width of the emission spectrum of the QD is broadened. Thus, the color purity which enables the satisfaction of the above-mentioned standard has not been achieved under the present conditions.

Patent Document 1 discloses a light-emitting element in which a tungsten oxide is used in a hole-injection layer and a quantum dot is used as a light-emitting substance.

### REFERENCE

### Patent Document

### [Patent Document 1] PCT International Publication No. 2012/013272

### SUMMARY OF THE INVENTION

An object of one embodiment of the present invention is to provide a light-emitting element with favorable efficiency and a sharp spectrum.

An object of one embodiment of the present invention is to provide a novel light-emitting element. Another object of one embodiment of the present invention is to provide a light-emitting element with favorable emission efficiency. Another object of one embodiment of the present invention is to provide a light-emitting element with favorable color purity.

Another object of one embodiment of the present invention is to provide a light-emitting device, an electronic device, and a display device each with low power consumption. Another object of one embodiment of the present invention is to provide a light-emitting device, an electronic device, and a display device each with favorable display quality.

It is only necessary that at least one of the above-described objects be achieved in the present invention.

One embodiment of the present invention is a light-emitting element including an anode, a cathode, and a layer including a light-emitting substance. The layer including the light-emitting substance is between the anode and the cathode. The layer including the light-emitting substance includes a light-emitting layer and an electron-transport layer. The electron-transport layer is between the light-emitting layer and the cathode. The light-emitting layer includes a metal-halide perovskite material. The electron-transport layer includes a 1,10-phenanthroline derivative including a 1,10-phenanthroline skeleton having a substituent at one of 2- and 9-positions or substituents at both of the 2- and 9-positions.

Another embodiment of the present invention is a light-emitting element including an anode, a cathode, and a layer including a light-emitting substance. The layer including the light-emitting substance is between the anode and the cathode. The layer including the light-emitting substance includes a light-emitting layer and an electron-transport layer. The electron-transport layer is between the light-emitting layer and the cathode. The light-emitting layer includes a metal-halide perovskite material represented by a general formula (SA)MX₃, a general formula (LA)₂(SA)ₙ₋₁MₙX₃ₙ₊₁or a general formula (PA)(SA)ₙ₋₁MₙX₃ₙ₊₁. The electron-transport layer includes a 1,10-phenanthroline derivative including a 1,10-phenanthroline skeleton having a substituent at one of 2- and 9-positions or substituents at both of the 2- and 9-positions.

Note that in the above general formulae, M represents a divalent metal ion, X represents a halogen ion, and n represents an integer greater than or equal to 1 and less than or equal to 10. Furthermore, LA represents an ammonium ion represented by R¹—NH₃⁺. In the formula, R¹ represents one or a plurality of an alkyl group having 2 to 20 carbon atoms, an aryl group having 6 to 20 carbon atoms, and a heteroaryl group having 4 to 20 carbon atoms. When R¹ represents the plurality of the alkyl group having 2 to 20 carbon atoms, the aryl group having 6 to 20 carbon atoms, and the heteroaryl group having 4 to 20 carbon atoms, a plurality of groups of the same kind or different kinds is used as R¹. Furthermore, PA represents NH₃⁺—R²-NH₃⁺, NH₃⁺—R³—R⁴—R⁵-NH₃⁺, or a part of a polymer including an ammonium cation, and the part has a valence of +2. Furthermore, R² represents a single-bond alkylene group or an alkylene group having 1 to 12 carbon atoms, R³ and R⁵ each independently represent a single-bond alkylene group or alkylene group having 1 to 12 carbon atoms, and R⁴ represents one or two of a cyclohexylene group and an arylene group having 6 to 14 carbon atoms. When R⁴ represents the two of the cyclohexylene group and the arylene group having 6 to 14 carbon atoms, a plurality of groups of the same kind or different kinds is used as R⁴. Furthermore, SA represents a monovalent metal ion or an ammonium ion represented by R⁶-NH₃⁺, and R⁶ represents an alkyl group having 1 to 6 carbon atoms.

Another embodiment of the present invention is the light-emitting element having the above-described structure, in which LA is any of ammonium ions represented by general formulae (A-1) to (A-11) and general formulae (B-1) to (B-6) shown below, and PA represents any of general formulae (C-1), (C-2), and (D) shown below and branched polyethyleneimine including ammonium cations.

In the above general formulae, R¹¹ represents an alkyl group having 2 to 18 carbon atoms, R¹², R¹³, and R¹⁴ represent hydrogen or an alkyl group having 1 to 18 carbon atoms, and R¹⁵ represents any of structural or general formulae (R¹⁵-1) to (R¹⁵-14) shown above. Furthermore, R¹⁶ and R¹⁷ each independently represent hydrogen or an alkyl group having 1 to 6 carbon atoms. In addition, X represents a combination of a monomer unit A and a monomer unit B represented by any of general formulae (D-1) to (D-6) shown above, and has a structure including monomer units A and monomer units B where the number of monomer units A is u and the number of monomer units B is v. Note that the arrangement order of the monomer units A and B is not limited. Furthermore, m and l are each independently an integer of 0 to 12, and t is an integer of 1 to 18. In addition, u is an integer of 0 to 17, v is an integer of 1 to 18, and u+v is an integer of 1 to 18.

Another embodiment of the present invention is the light-emitting element having the above-described structure which further includes an electron-injection buffer layer between the electron-transport layer and the cathode.

Another embodiment of the present invention is the light-emitting element having the above-described structure in which the electron-injection buffer layer includes an alkali metal or an alkaline earth metal.

Another embodiment of the present invention is the light-emitting element having the above-described structure in which the substituent at one of the 2- and 9-positions and the substituents at both of the 2- and 9-positions of the 1,10-phenanthroline skeleton in the 1,10-phenanthroline derivative each independently represent an aromatic hydrocarbon group having 6 to 18 carbon atoms.

Another embodiment of the present invention is the light-emitting element having the above-described structure in which the substituent at one of the 2- and 9-positions or the substituents at both of the 2- and 9-positions of the 1,10-phenanthroline skeleton in the 1,10-phenanthroline derivative are each a naphthyl group.

Another embodiment of the present invention is the light-emitting element having the above-described structure in which the 1,10-phenanthroline derivative including the 1,10-phenanthroline skeleton having the substituent at one of the 2- and 9-positions or the substituents at both of the 2- and 9-positions is 2,9-bis(naphthalen-2-yl)-4,7-diphenyl-1,10-phenanthroline.

Another embodiment of the present invention is the light-emitting element having the above-described structure in which the electron-transport layer includes a first electron-transport layer including a first substance and a second electron-transport layer including a second substance, the first electron-transport layer is between the second electron-transport layer and the light-emitting layer, the second electron-transport layer is between the first electron-transport layer and the cathode, and the second substance is the 1,10-phenanthroline derivative including the 1,10-phenanthroline skeleton having the substituents at both of the 2- and 9-positions.

Another embodiment of the present invention is the light-emitting element having the above-described structure in which the metal-halide perovskite material is a particle including a longest part of 1 μm or less.

Another embodiment of the present invention is the light-emitting element having the above-described structure in which the metal-halide perovskite material has a layered structure in which a perovskite layer and an organic layer are stacked.

Another embodiment of the present invention is a light-emitting device including the light-emitting element with any of the above structures, and a transistor or a substrate.

Another embodiment of the present invention is an electronic device including the light-emitting device with any of the above structures, and a sensor, an operation button, a speaker, or a microphone.

Another embodiment of the present invention is a lighting device including the light-emitting device with any of the above structures, and a housing.

Another embodiment of the present invention is a light-emitting device including the light-emitting element with any of the above structures, a substrate, and a transistor.

Another embodiment of the present invention is an electronic device including the light-emitting device with any of the above structures, and a sensor, an operation button, a speaker, or a microphone.

Another embodiment of the present invention is a lighting device including the light-emitting device with any of the above structures, and a housing.

Note that the light-emitting device in this specification includes, in its category, an image display device that uses a light-emitting element. The light-emitting device may include a module in which a light-emitting element is provided with a connector such as an anisotropic conductive film or a tape carrier package (TCP), a module in which a printed wiring board is provided at the end of a TCP, and a module in which an integrated circuit (IC) is directly mounted on a light-emitting element by a chip on glass (COG) method. Furthermore, the light-emitting device may be included in lighting equipment or the like.

In one embodiment of the present invention, a novel light-emitting element can be provided. In another embodiment of the present invention, a light-emitting element with a long lifetime can be provided. In another embodiment of one embodiment of the present invention, a light-emitting element with favorable emission efficiency can be provided.

In another embodiment of the present invention, a highly reliable light-emitting device, a highly reliable electronic device, and a highly reliable display device can be provided. In another embodiment of the present invention, a light-emitting device, an electronic device, and a display device each with low power consumption can be provided.

Note that the description of these effects does not preclude the existence of other effects. One embodiment of the present invention does not necessarily achieve all the effects listed above. Other effects will be apparent from and can be derived from the description of the specification, the drawings, the claims, and the like.

### BRIEF DESCRIPTION OF THE DRAWINGS

FIGS. 1A to 1C are schematic diagrams of light-emitting elements.

FIGS. 2A to 2D illustrate an example of a method for manufacturing a light-emitting element.

FIG. 3 illustrates an example of a method for manufacturing a light-emitting element.

FIGS. 4A and 4B are schematic diagrams of an active matrix light-emitting device.

FIGS. 5A and 5B are schematic diagrams of active matrix light-emitting devices.

FIG. 6 is a schematic diagram of an active matrix light-emitting device.

FIGS. 7A and 7B are schematic diagrams of a passive matrix light-emitting device.

FIGS. 8A and 8B illustrate a lighting device.

FIGS. 9A, 9B1, 9B2, 9C, and 9D each illustrate an electronic device.

FIG. 10 illustrates a light source device.

FIG. 11 illustrates a lighting device.

FIG. 12 illustrates a lighting device.

FIG. 13 illustrates car-mounted display devices and lighting devices.

FIGS. 14A to 14C illustrate an electronic device.

FIGS. 15A to 15C illustrate an electronic device.

FIG. 16 shows luminance-current density characteristics of a light-emitting element 1 and a comparative light-emitting element 1.

FIG. 17 shows current efficiency-luminance characteristics of a light-emitting element 1 and a comparative light-emitting element 1.

FIG. 18 shows luminance-voltage characteristics of a light-emitting element 1 and a comparative light-emitting element 1.

FIG. 19 shows current-voltage characteristics of a light-emitting element 1 and a comparative light-emitting element 1.

FIG. 20 shows external quantum efficiency-luminance characteristics of a light-emitting element 1 and a comparative light-emitting element 1.

FIG. 21 shows emission spectra of a light-emitting element 1 and a comparative light-emitting element 1.

FIG. 22 shows luminance-current density characteristics of a light-emitting element 2 and a light-emitting element 3.

FIG. 23 shows current efficiency-luminance characteristics of a light-emitting element 2 and a light-emitting element 3.

FIG. 24 shows luminance-voltage characteristics of a light-emitting element 2 and a light-emitting element 3.

FIG. 25 shows current-voltage characteristics of a light-emitting element 2 and a light-emitting element 3.

FIG. 26 shows external quantum efficiency-luminance characteristics of a light-emitting element 2 and a light-emitting element 3.

FIG. 27 shows emission spectra of a light-emitting element 2 and a light-emitting element 3.

### DETAILED DESCRIPTION OF THE INVENTION

Embodiments of the present invention will be described below with reference to the drawings. It will be readily appreciated by those skilled in the art that modes and details of the present invention can be modified in various ways without departing from the spirit and scope of the present invention. Thus, the present invention should not be construed as being limited to the description in the following embodiments.

### Embodiment 1

A metal-halide perovskite material is a composite material of an organic material and an inorganic material or a material formed of only an inorganic material, and has some interesting properties such as light emission by excitons or high carrier mobility (hereinafter, this material is referred to as a metal-halide perovskite material). The metal-halide perovskite material has a superstructure in which inorganic layers (also referred to as perovskite layers) and organic layers are alternately stacked, which forms a quantum well structure. Therefore, the metal-halide perovskite material exhibits particularly high exciton binding energy, so that excitons can exist stably. Furthermore, the metal-halide perovskite material has a narrow half width and exhibits light emission by exciton with a small Stokes shift; thus, usage in a light-emitting element is expected. Moreover, a quantum dot of the metal-halide perovskite material is also known as a substance that exhibits favorable color-purity light emission with an extremely narrow half width.

In addition, because the metal-halide perovskite material has an excellent self-assembly property, a thin film sample or a single crystal sample can be easily formed with a wet process by only applying a solution of the raw material. A favorable light-emitting layer can also be formed by using a quantum dot of the metal-halide perovskite material with a size of several tens of nanometers to several hundreds of nanometers.

Moreover, a light-emitting element in which the metal-halide perovskite material is used as a light-emitting substance can be formed to be light and thin, can be easily formed as a planar light source, can be used to form a minute pixel, and can be bent, for example, like an organic EL element containing an organic compound as a light-emitting substance (hereinafter, such an element is also referred to as an OLED element). In addition, a light-emitting element using the metal-halide perovskite material as a light-emitting substance can be comparable to or advantageous over an OLED element in color purity, lifetime, efficiency, emission wavelength selection facility, and the like.

Like an OLED element, a light-emitting element using the metal-halide perovskite material as a light-emitting substance can emit light when a current is fed through an EL layer that is provided between an anode and a cathode and includes a light-emitting layer containing the metal-halide perovskite material as a light-emitting substance. The EL layer may include functional layers such as a hole injection/transport layer, an electron injection/transport layer, and a buffer layer and other functional layers, in addition to the light-emitting layer. The hole injection/transport layer and the electron injection/transport layer each have functions of transporting a carrier injected from an electrode and injecting the carrier into the light-emitting layer.

Because the VB maximum and the conduction band minimum of the metal-halide perovskite material are positioned close to those of an organic compound which is a light-emitting substance for an OLED element, materials similar to those for the OLED element can be used as the above-described functional layers.

However, a light-emitting element using the metal-halide perovskite material as a light-emitting substance cannot emit light with favorable efficiency conventionally. According to the consideration by the present inventors, one of the possible reasons for the insufficient efficiency is quenching by a sensitive reaction with an alkali metal or an alkaline earth metal that is used for electron injection.

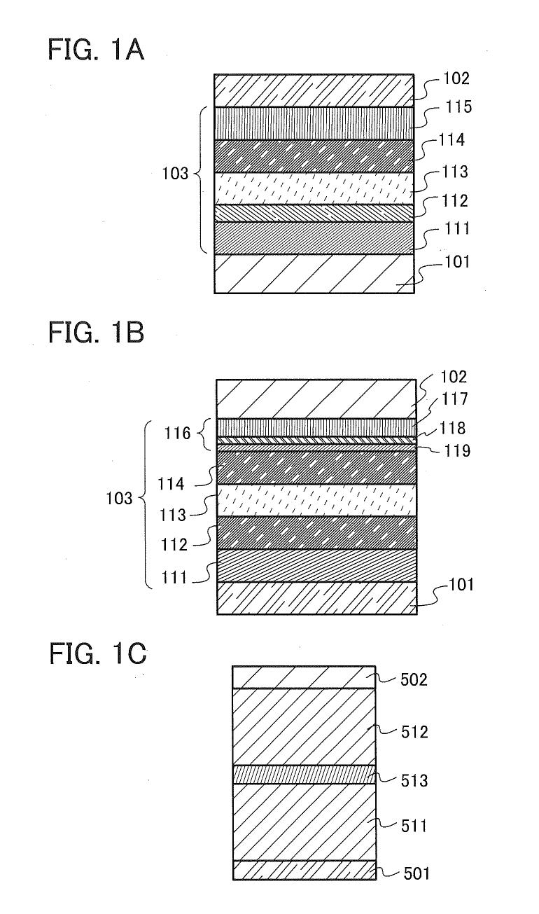

In a light-emitting element of this embodiment, as shown in FIGS. 1A and 1B, a layer 103 containing a light-emitting substance is positioned between an anode 101 and a cathode 102, and the layer 103 containing a light-emitting substance includes a light-emitting layer 113 and an electron-transport layer 114. The light-emitting layer 113 includes a metal-halide perovskite material, and the metal-halide perovskite material in the light-emitting element of this embodiment emits light.

The electron-transport layer 114 includes a 1,10-phenanthroline derivative in which a 1,10-phenanthroline skeleton has a substituent at one of the 2- and 9-positions or substituents at both of the 2- and 9-positions. The present inventors have found that such a structure significantly increases the emission efficiency compared with the emission efficiency of the case of using the electron-transport layer 114 that includes a 1,10-phenanthroline derivative in which both of the 2- and 9-positions of a 1,10-phenanthroline skeleton are unsubstituted. This is presumed to be because the substituent at one of the 2- and 9-positions or the substituents at both of the 2- and 9-positions of the 1,10-phenanthroline skeleton suppress the diffusion of an alkali metal or an alkaline earth metal. It is preferable that the substituent and the substituents each independently represent an alkyl group having 1 to 18 carbon atoms or an aryl group having 6 to 18 carbon atoms. It is further preferable that the substituent and the substituents each independently represent an aryl group having 6 to 18 carbon atoms. In terms of heat resistance and an electron-transport property, it is preferable that the substituent and the substituents be each a naphthyl group. In terms of enhancing the property of injecting an electron from the cathode, it is further preferable that the substituent and the substituents be each a 2-naphthyl group.

When the electron-transport layer 114 includes the 1,10-phenanthroline derivative in which the 1,10-phenanthroline skeleton has the substituent at one of the 2- and 9-positions or the substituents at both of the 2- and 9-positions, the diffusion of an alkali metal or an alkaline earth metal can be suppressed while maintaining the electron-transport property or the electron-injection property. Accordingly, quenching of light emitted from the metal-halide perovskite material serving as a light-emitting substance, which is caused by the diffusion of an alkali metal or an alkaline earth metal to the light-emitting layer 113, can be suppressed. Thus, the light-emitting element of one embodiment of the present invention can emit light with favorable emission efficiency. In terms of preventing the diffusion of an alkali metal or an alkaline earth metal, it is preferable that the 1,10-phenanthroline skeleton have the substituents at both of the 2- and 9-positions.

Note that the electron-transport layer 114 may include a stack of layers formed of different materials.

In addition to these layers, a hole-injection layer 111, a hole-transport layer 112, an electron-injection buffer layer 115, and other layers may be included in the layer 103 containing a light-emitting substance.

The metal-halide perovskite material contained in the light-emitting layer 113 can be represented by any of general formulae (G1) to (G3) shown below.

(SA)MX₃ (G1)

(LA)₂(SA)ₙ₋₁MₙX₃ₙ₊₁ (G2)

(PA)(SA)ₙ₋₁MₙX₃ₙ₊₁ (G3)

In the above general formulae, M represents a divalent metal ion, and X represents a halogen ion.

Specific examples of the divalent metal ion are divalent cations of lead, tin, or the like.

Specific examples of the halogen ion are anions of chlorine, bromine, iodine, fluorine, or the like.

Note that n represents an integer of 1 to 10. In the case where n is larger than 10 in the general formula (G2) or (G3), the metal-halide perovskite material has properties close to those of the metal-halide perovskite material represented by the general formula (G1).

Moreover, LA is an ammonium ion represented by R¹-NH₃⁺.

In the ammonium ion represented by R¹-NH₃⁺, R¹ represents any one of an alkyl group having 2 to 20 carbon atoms, an aryl group having 6 to 20 carbon atoms, and a heteroaryl group having 4 to 20 carbon atoms. Alternatively, R¹ represents a group in which an alkyl group having 2 to 20 carbon atoms, an aryl group having 6 to 20 carbon atoms, or a heteroaryl group having 4 to 20 carbon atoms is combined with an alkylene group having 1 to 12 carbon atoms, a vinylene group, an arylene group having 6 to 13 carbon atoms, and a heteroarylene group. In the latter case, a plurality of alkylene groups, vinylene groups, arylene groups, and heteroarylene groups may be coupled, and a plurality of groups of the same kind may be included. In the case where a plurality of alkylene groups, vinylene groups, arylene groups, and heteroarylene groups are coupled, the total number of alkylene groups, vinylene groups, arylene groups, and heteroarylene groups is preferably smaller than or equal to 35.

Furthermore, SA represents a monovalent metal ion or an ammonium ion represented by R⁶-NH₃+in which R⁶ is an alkyl group having 1 to 6 carbon atoms.

Moreover, PA represents NH₃⁺—R²—NH₃⁺, NH₃⁺—R³—R⁴—R⁵—NH₃⁺, or a part or whole of branched polyethyleneimine including ammonium cations, and the valence of PA is +2. Note that charges are roughly in balance in the general formula.

Here, charges of the metal-halide perovskite material are not necessarily in balance strictly in every portion of the material in the above formula as long as the neutrality is roughly maintained in the material as a whole. In some cases, other ions such as a free ammonium ion, a free halogen ion, or an impurity ion exist locally in the material and neutralize the charges. In addition, in some cases, the neutrality is not maintained locally also at a surface of a particle or a film, a crystal grain boundary, or the like; thus, the neutrality is not necessarily maintained in every location.

Note that in the above formula (G2), (LA) can be any of substances represented by general formulae (A-1) to (A-11) and general formulae (B-1) to (B-6) shown below, for example.

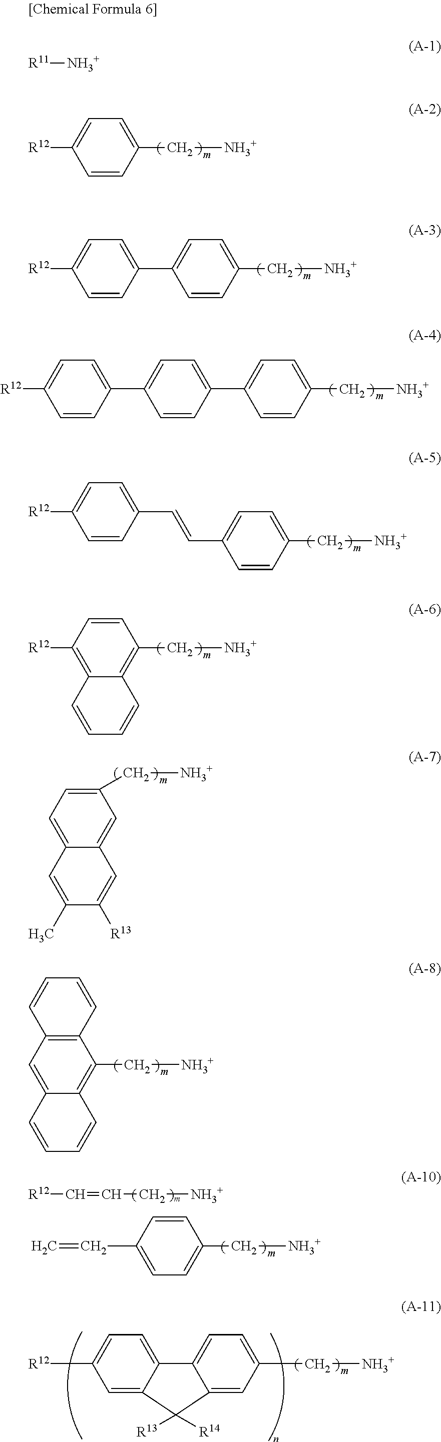

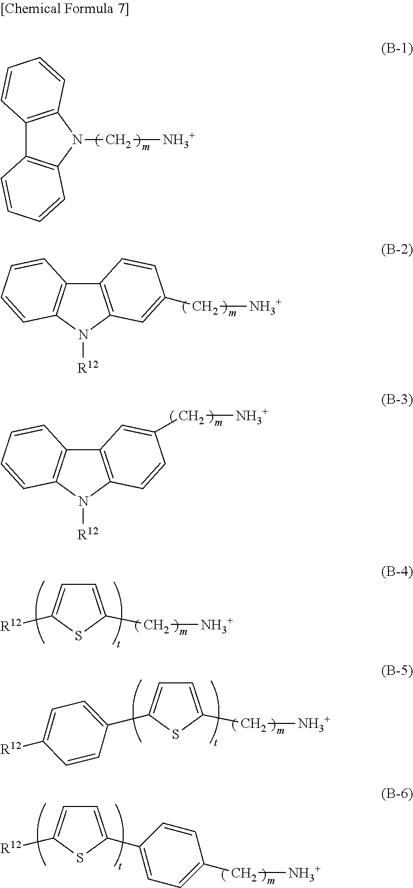

Furthermore, (PA) in the general formula (G3) is typically any of substances represented by general formulae (C-1), (C-2), and (D) shown below or a part or whole of branched polyethyleneimine including ammonium cations, and the valence of (PA) is +2. These polymers may neutralize charges over a plurality of unit cells. Alternatively, one charge of each of two different polymer molecules may neutralize charges of one unit cell.

Note that in the above general formulae, R¹¹ represents an alkyl group having 2 to 18 carbon atoms, R^{12,} R^{13,} and R¹⁴ represent hydrogen or an alkyl group having 1 to 18 carbon atoms, and R¹⁵ represents any of structural or general formulae (R¹⁵-1) to

(R¹⁵-14) shown below. Furthermore, R¹⁶ and R¹⁷ each independently represent hydrogen or an alkyl group having 1 to 6 carbon atoms. In addition, X represents a combination of a monomer unit A and a monomer unit B represented by any of the general formulae (D-1) to (D-6) shown above, and has a structure including monomer units A and monomer units B where the number of monomer units A is u and the number of monomer units B is v. Note that the arrangement order of the monomer units A and B is not limited. Furthermore, in and 1 are each independently an integer of 0 to 12, and t is an integer of 1 to 18. In addition, u is an integer of 0 to 17, v is an integer of 1 to 18, and u +v is an integer of 1 to 18.

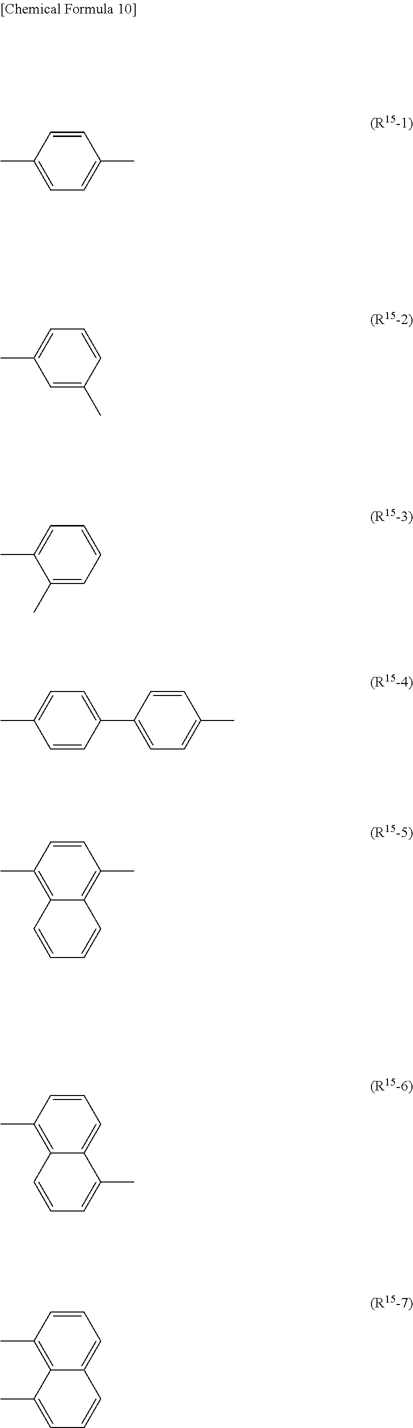

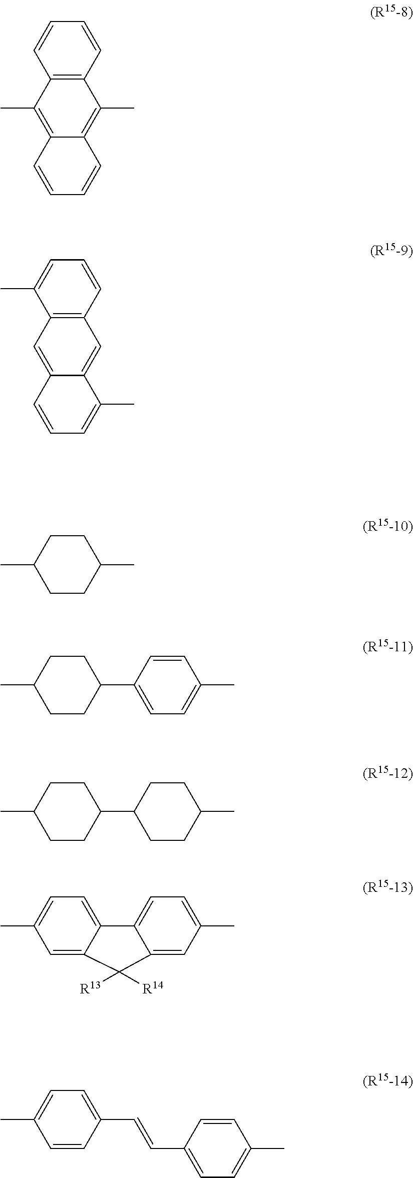

The substances that can be used as (LA) and (PA) may be, but not limited to, the above-described examples.

The metal-halide perovskite material having a three-dimensional structure including the composition (SA)MX₃ represented by the general foimula (G1) includes regular octahedron structures each of which has a metal atom M at the center and six halogen atoms at the vertexes. Such regular octahedron structures are three-dimensionally arranged by sharing the halogen atoms of the vertexes, so that a skeleton is formed. This octahedral structure unit including a halogen atom at each vertex is referred to as a perovskite unit. There are a zero-dimensional structure body in which a perovskite unit exists in isolation, a linear structure body in which perovskite units are one-dimensionally coupled with a halogen atom at the vertex, a sheet-shaped structure body in which perovskite units are two-dimensionally coupled, and a structure body in which perovskite units are three-dimensionally coupled. Furthermore, there are also a complicated two-dimensional structure body in which a plurality of sheet-shaped structure bodies having two-dimensionally coupled perovskite units are stacked, and more complicated structure bodies. All of these structure bodies having a perovskite unit are collectively defined as a metal-halide perovskite material.

In the three-dimensional structure body in which halogen atoms of all the perovskite units are coupled three-dimensionally, each perovskite unit is negatively charged and the negatively-charged perovskite unit is monovalent. In addition, a monovalent SA cation located at a site surrounded by the coupled perovskite units neutralizes the negative charges. In the other structure bodies, some halogen atoms forming the octahedrons do not share the vertexes of the octahedrons, and thus the negatively-charged perovskite units are not monovalent. Accordingly, the percentage of contained cations which cancel out the negative charges of the perovskite units changes depending on how the perovskite units are coupled. In the three-dimensional perovskite, the size of cations is limited by the size of the gap between the coupled perovskite skeletons. In the other structure bodies, the size and shape of cations dominate the coupling form of the perovskite units reversely, which increases the material design flexibility. Accordingly, a variety of perovskite structure bodies can be devised by molecular design of the size and shape of cation species which are an organic amine.

The metal-halide perovskite materials represented by the general formula (G2) or (G3) are special two-dimensional perovskite materials having a structure in which a plurality of layers of the two-dimensional structure bodies (also referred to as perovskite layers or inorganic layers) of the above-described metal-halide perovskite material are stacked and segregated by a variety of sizes and shapes of organic ions (corresponding to (LA) and (PA) in the above formulae).

The thickness of the light-emitting layer 113 is 3 nm to 1000 nm, preferably 10 nm to 100 nm, and the metal-halide perovskite material content of the light-emitting layer is 1 vol % to 100 vol %. Note that the light-emitting layer is preferably formed of only the metal-halide perovskite material. The light-emitting layer including the metal-halide perovskite material can typically be formed by a wet process (e.g., a spin coating method, a casting method, a die coating method, a blade coating method, a roll coating method, an inkjet method, a printing method, a spray coating method, a curtain coating method, or a Langmuir-Blodgett method) or a vacuum evaporation method.

Specifically, in the case of using a wet process, a solution obtained by dissolving a metal halide corresponding to M and X in the above general formulae and organic ammonium corresponding to (SA), (LA), or (PA) in a liquid medium is applied and dried, or quantum dots of the metal-halide perovskite material are dispersed in a liquid medium and then applied and dried. Thus, the light-emitting layer 113 can be formed. In the case of using an evaporation method, a method of vapor depositing the metal-halide perovskite material by a vacuum evaporation method, a method of co-evaporating a metal halide and organic ammonium, or the like can be employed. Alternatively, other methods may be employed for the film formation.

To form a light-emitting layer in which quantum dots of the metal-halide perovskite material are dispersed as a light-emitting material in a host material, the quantum dots may be dispersed in the host material, or the host material and the quantum dots may be dissolved or dispersed in an appropriate liquid medium, and then a wet process (e.g., a spin coating method, a casting method, a die coating method, a blade coating method, a roll coating method, an ink-jet method, a printing method, a spray coating method, a curtain coating method, or a Langmuir-Blodgett method) or co-evaporation using a vacuum evaporation method may be employed. For a light-emitting layer containing the metal-halide perovskite material, a vacuum evaporation method, as well as the wet process, can be suitably employed.

An example of the liquid medium used for the wet process is an organic solvent of ketones such as methyl ethyl ketone and cyclohexanone; fatty acid esters such as ethyl acetate; halogenated hydrocarbons such as dichlorobenzene; aromatic hydrocarbons such as toluene, xylene, mesitylene, and cyclohexylbenzene; aliphatic hydrocarbons such as cyclohexane, decalin, and dodecane; dimethylformamide (DMF); dimethyl sulfoxide (DMSO); or the like.

Quantum dots of the metal-halide perovskite material can have a variety of shapes such as a rod shape, a plate shape, and a spherical shape, in addition to a cube shape. The size is smaller than or equal to 1 μm, preferably smaller than or equal to 500 nm.

As the electron-injection buffer layer 115, an alkali metal, an alkaline earth metal, or a compound thereof such as lithium fluoride (LiF), cesium fluoride (CsF), or calcium fluoride (CaF₂) is preferably used. Alternatively, a layer that contains a substance having an electron-transport property and an alkali metal, an alkaline earth metal, a compound thereof, or an electride may be used. Examples of the electride include a substance in which electrons are added at high concentration to calcium oxide-aluminum oxide.

Although the electron-transport layer 114 and the electron-injection buffer layer 115 can be formed by a vacuum evaporation method, they may be formed by another method as well.

The stacked structure and each component of the layer 103 containing a light-emitting substance on the cathode 102 side of the light-emitting layer 113 have been described above. Next, the stacked structure and each component of the layer 103 containing a light-emitting substance on the anode 101 side of the light-emitting layer 113 will be described.

For the light-emitting layer using the metal-halide perovskite material as a light-emitting substance, the hole-injection layer 111 and the hole-transport layer 112 can be formed using materials similar to those used in an OLED element. However, because a film of the metal-halide perovskite material can be formed by a wet process such as spin coating or blade coating, it is preferable to form the hole-injection layer 111 and the hole-transport layer 112 also by a wet process.

In the case where the hole-transport layer 112 is formed by a wet process, it can be formed using a high-molecular compound such as poly(N-vinylcarbazole) (abbreviation: PVK), poly(-vinyltriphenylamine) (abbreviation: PVTPA), poly[N-(4-{N-[4-(4-diphenylamino)phenyl]phenyl-N-phenylamino}phenyl)methacryla mide] (abbreviation: PTPDMA), or poly[N,N-bis(4-butylphenyl)-N,N-bis(phenyl)benzidine] (abbreviation: Poly-TPD).

In the case where the hole-injection layer 111 is formed by a wet process, it can be formed using a conductive high-molecular compound to which an acid is added, such as a poly(3,4-ethylenedioxythiophene)/poly(styrenesulfonic acid) aqueous solution (PEDOT/PSS), a polyaniline/camphor sulfonic acid aqueous solution (PANI/CSA), PTPDES, Et-PTPDEK, PPBA, or polyaniline/poly(styrenesulfonic acid) (PANI/PSS), for example.

A method other than a wet process may be used to form the hole-transport layer 112 and the hole-injection layer 111.

In this case, the hole-injection layer 111 is formed using a first substance having a relatively high acceptor property. Preferably, the hole-injection layer 111 is formed using a composite material in which the first substance having an acceptor property and a second substance having a hole-transport property are mixed. As the first substance, a substance having an acceptor property with respect to the second substance is used. The first substance draws electrons from the second substance, so that electrons are generated in the first substance. In the second substance from which electrons are drawn, holes are generated. By an electric field, the drawn electrons flow to the anode 101 and the generated holes are injected to the light-emitting layer 113 through the hole-transport layer 112.

The first substance is preferably a transition metal oxide, an oxide of a metal belonging to any of Groups 4 to 8 in the periodic table, an organic compound having an electron-withdrawing group (a halogen group or a cyano group), or the like.

As the transition metal oxide or the oxide of a metal belonging to any of Groups 4 to 8 in the periodic table, a vanadium oxide, a niobium oxide, a tantalum oxide, a chromium oxide, a molybdenum oxide, a tungsten oxide, a manganese oxide, a rhenium oxide, a titanium oxide, a ruthenium oxide, a zirconium oxide, a hafnium oxide, or a silver oxide is preferable because of its high electron acceptor property. A molybdenum oxide is particularly preferable because of its high stability in the air, low hygroscopicity, and high handiness.

Examples of the compound having an electron-withdrawing group (a halogen group or a cyano group) include 7,7,8,8-tetracyano-2,3,5,6-tetrafluoroquinodimethane (abbreviation: F₄-TCNQ), chioranil, 2,3,6,7,10,11-hexacyano-1,4,5,8,9,12-hexaazatriphenylene (abbreviation: HAT-CN), and 1,3,4,5,7,8-hexafluorotetracyano-naphthoquinodimethane (abbreviation: F6-TCNNQ). In particular, a compound in which electron-withdrawing groups are bonded to a condensed aromatic ring having a plurality of heteroatoms, like HAT-CN, is thermally stable and preferable.

The second substance is a substance having a hole-transport property, and has a hole mobility greater than or equal to 10⁴ cm²/Vs. Examples of the material of the second substance include aromatic amines such as N,N-di(p-tolyl)-N,N-diphenyl-p-phenylenediamine (abbreviation: DTDPPA), 4,4′-bis[N-(4-diphenylaminophenyl)-N-phenylamino]biphenyl (abbreviation: DPAB), N,N-bis{4-[bis(3-methylphenyl)amino]phenyl}-N,N-diphenyl-(1,1′-biphenyl)-4,4′-diamine (abbreviation: DNTPD), and 1,3,5-tris[N-(4-diphenylaminophenyl)-N-phenylamino]benzene (abbreviation: DPA3B); carbazole derivatives such as 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 4,4′-di(N-carbazolyl)biphenyl (abbreviation: CBP), 1,3,5-tris[4-(N-carbazolyl)phenyl]benzene (abbreviation: TCPB), 9-[4-(10-phenyl-9-anthryl)phenyl]-9H-carbazole (abbreviation: CzPA), and 1,4-bis[4-(N-carbazolyl)phenyl]-2,3,5,6-tetraphenylbenzene; and aromatic hydrocarbons such as 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation:

t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tert-butyl-9,10-bis[2-(1-naphthyl)phenyl]anthracene, 9,10-bis[2-(1-naphthyl)phenyl]anthracene, 2,3 ,6,7-tetramethyl-9,10-di(1-naphthyl)anthracene, 2,3 ,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, pentacene, coronene, rubrene, perylene, and 2,5,8,11-tetra(tert-butyl)perylene. The aromatic hydrocarbon may have a vinyl skeleton. As the aromatic hydrocarbon having a vinyl group, the following are given for example: 4,4′-bis(2,2-diphenylvinyl)biphenyl (abbreviation: DPVBi); 9,10-bis[4-(2,2-diphenylvinyl)phenyl]anthracene (abbreviation: DPVPA); and the like. Furthermore, a compound having an aromatic amine skeleton such as 4,4′-bis[N-(1-naphthyl)-N-phenylamino]biphenyl (abbreviation: NPB), N,N′-bis(3-methylphenyl)-N,N-diphenyl-[1,1′-biphenyl]-4,4′-diamine (abbreviation: TPD), 4,4′-bis[N-(spiro-9,9′-bifluoren-2-yl)-N-phenylamino]biphenyl (abbreviation: BSPB), 4-phenyl-4′-(9-phenyffluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N- [4-(9-phenyl-9H-carbazol-3-yl)phenyl]fluoren-2-amine (abbreviation: PCBAF), or N-phenyl-N-[4-(9-phenyl-9H-carbazol-3-yl)phenyl]spiro-9,9′-bifluoren-2-amine (abbreviation: PCBASF); a compound having a carbazole skeleton such as 1,3-bis(N-carbazolyl)benzene (abbreviation: mCP), 4,4′-di(N-carbazolyObiphenyl (abbreviation: CBP), 3,6-bis(3,5-diphenylphenyl)-9-phenylcarbazole (abbreviation: CzTP), or 3,3′-bis(9-phenyl-9H-carbazole) (abbreviation: PCCP); a compound having a thiophene skeleton such as 4,4′,4″-(benzene- 1,3 ,5-triyOtri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV); or a compound having a furan skeleton such as 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II) can be used. Among the above-described materials, a compound having an aromatic amine skeleton and a compound having a carbazole skeleton are preferable because these compounds are highly reliable and have high hole-transport properties to contribute to a reduction in drive voltage.

The hole-transport layer 112 can be formed using any of the above-described materials for the second substance.

The anode 101 is preferably formed using any of metals, alloys, electrically conductive compounds with a high work function (specifically, a work function of 4.0 eV or more), mixtures thereof, and the like. Specific examples are indium oxide-tin oxide (ITO: indium tin oxide), indium oxide-tin oxide containing silicon or silicon oxide, indium oxide-zinc oxide, indium oxide containing tungsten oxide and zinc oxide (IWZO), and the like. Films of these electrically conductive metal oxides are usually formed by a sputtering method but may be formed by application of a sol-gel method or the like. In an example of the formation method, indium oxide-zinc oxide can be deposited by a sputtering method using a target in which zinc oxide is added to indium oxide at greater than or equal to 1 wt % and less than or equal to 20 wt %. Furthermore, indium oxide containing tungsten oxide and zinc oxide (IWZO) can be deposited by a sputtering method using a target in which, to indium oxide, tungsten oxide is added at greater than or equal to 0.5 wt % and less than or equal to 5 wt % and zinc oxide is added at greater than or equal to 0.1 wt % and less than or equal to 1 wt %. Other examples include gold (Au), platinum (Pt), nickel (Ni), tungsten (W), chromium (Cr), molybdenum (Mo), iron (Fe), cobalt (Co), copper (Cu), palladium (Pd), aluminum (Al), and nitrides of metal materials (e.g., titanium nitride). Graphene can also be used. In the case where the hole-injection layer 111 includes a composite material including the first substance and the second substance, an electrode material other than the above can be selected regardless of the work function.

Examples of a substance contained in the cathode 102 include an element belonging to Group 1 or 2 in the periodic table such as an alkali metal (e.g., lithium (Li) or cesium (Cs)), magnesium (Mg), calcium (Ca), or strontium (Sr) or an alloy containing the element (MgAg or AlLi); a rare earth metal such as europium (Eu) or ytterbium (Yb) or an alloy containing the metal; ITO; indium oxide-tin oxide containing silicon or silicon oxide; indium oxide-zinc oxide; and indium oxide containing tungsten oxide and zinc oxide (IWZO). Any of a variety of conductive materials such as aluminum (Al), silver (Ag), indium tin oxide (ITO), and indium oxide-tin oxide containing silicon or silicon oxide can be used for the cathode 102. A dry method such as a vacuum evaporation method or a sputtering method, an ink-jet method, a spin coating method, or the like can be used for depositing these conductive materials. Alternatively, a wet method using a sol-gel method, or a wet method using a paste of a metal material can be used.

Instead of the electron-injection buffer layer 115, a charge-generation layer 116 may be provided (FIG. 1B). The charge-generation layer 116 refers to a layer capable of injecting holes into a layer in contact with the cathode side of the charge-generation layer 116 and electrons into a layer in contact with the anode side thereof when a potential is applied. The charge-generation layer 116 includes at least a p-type layer 117. The p-type layer 117 is preferably formed using any of the above-described materials that can be used for the hole-injection layer 111, in particular, the composite material. The p-type layer 117 may be formed by stacking a film containing the above-described acceptor material as a material included in the composite material and a film containing the above-described hole-transport material. When a potential is applied to the p-type layer 117, electrons are injected into the electron-transport layer 114 and holes are injected into the cathode 102; thus, the light-emitting element operates.

Note that the charge-generation layer 116 preferably includes either an electron-relay layer 118 or an electron-injection buffer layer 119 or both in addition to the p-type layer 117.

The electron-relay layer 118 contains at least the substance having an electron-transport property and has a function of preventing an interaction between the electron-injection buffer layer 119 and the p-type layer 117 and smoothly transferring electrons. The LUMO level of the substance with an electron-transport property contained in the electron-relay layer 118 is preferably between the LUMO level of an acceptor substance in the p-type layer 117 and the LUMO level of a substance contained in a layer of the electron-transport layer 114 in contact with the charge-generation layer 116. As a specific value of the energy level, the LUMO level of the substance having an electron-transport property in the electron-relay layer 118 is preferably higher than or equal to −5.0 eV, further preferably higher than or equal to −5.0 eV and lower than or equal to −3.0 eV. Note that as the substance having an electron-transport property in the electron-relay layer 118, a phthalocyanine-based material or a metal complex having a metal-oxygen bond and an aromatic ligand is preferably used.

A substance having a high electron-injection property can be used for the electron-injection buffer layer 119. For example, an alkali metal, an alkaline earth metal, a rare earth metal, or a compound thereof (e.g., an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)) can be used.

In the case where the electron-injection buffer layer 119 contains the substance having an electron-transport property and a donor substance, an organic compound such as tetrathianaphthacene (abbreviation: TTN), nickelocene, or decamethylnickelocene can be used as the donor substance, as well as an alkali metal, an alkaline earth metal, a rare earth metal, a compound of the above metal (e.g., an alkali metal compound (including an oxide such as lithium oxide, a halide, and a carbonate such as lithium carbonate or cesium carbonate), an alkaline earth metal compound (including an oxide, a halide, and a carbonate), and a rare earth metal compound (including an oxide, a halide, and a carbonate)). As the substance having an electron-transport property, a substance with an electron mobility of 10⁻⁶ cm²/Vs or more is preferable. Specific examples thereof include metal complexes such as bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), and bis[2-(2-benzothiazolyl)phenolato]zinc(II) (abbreviation: ZnBTZ). Furthermore, a heterocyclic compound having a polyazole skeleton can also be used, and for example, an oxadiazole derivative such as 2-(4-biphenylyl)-5-(4-tent-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), or 9- [4-(5-phenyl-1,3,4-oxadiazol-2-yl)phenyl]-9H-carbazole (abbreviation: CO11); a triazole derivative such as 3-(4-biphenylyl)-4-phenyl-5-(4-tent-butylphenyl)-1,2,4-triazole (abbreviation: TAZ); and a benzimidazole derivative such as 2,2′,2″-(1,3,5-benzene triyOtris(1-phenyl-1H-benzimidazole) (abbreviation: TPBI) or 2-[3-(dibenzothiophen-4-yl)phenyl]-1-phenyl-1H-benzimidazole (abbreviation: mDBTBIm-II) can be given. Furthermore, a heterocyclic compound having a diazine skeleton such as 2- [3-(dibenzothiophen-4-yOphenyl]dibenzo[f,h]quinoxaline (abbreviation: 2mDBTPDBq-II), 2-[3′-(dibenzothiophen-4-yl)biphenyl-3-yl] dibenzo[fh]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 4,6-bis[3-(phenanthren-9-yl)phenyl]pyrimidine (abbreviation: 4,6mPnP2Pm), or 4,6-bis[3-(4-dibenzothienyl)phenyl]pyrimidine (abbreviation: 4,6mDBTP2Pm-II); a heterocyclic compound having a triazine skeleton such as 2,4,6-tris(biphenyl-3-yl)-1,3,5-triazine (abbreviation: T2T), 2,4,6-tris-[3′-(pyridin-3-yl)biphenyl-3-yl]- 1,3 ,5-triazine (abbreviation: TmPPPyTz), 9-(4,6-diphenyl-1,3 ,5-triazin-2-yl)-9′-phenyl-9H,9′H-3,3′-bicarbazole (abbreviation:

CzT), or 2- {3- [3-(dibenzothiophen-4-yl)phenyl]phenyl}-4,6-diphenyl-1,3,5-triazine (abbreviation: mDBtBPTzn); and a heterocyclic compound having a pyridine skeleton such as 3,5-bis[3-(9H-carbazol-9-yl)phenyl]pyridine (abbreviation: 35DCzPPy) or 1,3,5-tri[3-(3-pyridyl)phenyl]benzene (abbreviation: TmPyPB) can be given. Among the above-described materials, the heterocyclic compound having a diazine skeleton, the heterocyclic compound having a triazine skeleton, and the heterocyclic compound having a pyridine skeleton have high reliability and are thus preferable. The heterocyclic compound having a diazine (pyrimidine or pyrazine) skeleton and the heterocyclic compound having a triazine skeleton have an excellent electron-transport property and contribute to a decrease in drive voltage.

An n-type compound semiconductor may also be used, and an oxide such as titanium oxide (TiO₂), zinc oxide (ZnO), silicon oxide (SiO₂), tin oxide (SnO₂), tungsten oxide (WO₃), tantalum oxide (Ta₂O₃), barium titanate (BaTiO₃), barium zirconate (BaZrO₃), zirconium oxide (ZrO₂), hafnium oxide (HfO₂), aluminum oxide (Al₂O₃), yttrium oxide (Y₂O₃), or zirconium silicate (ZrSiO₄); a nitride such as silicon nitride (Si₃N₄); cadmium sulfide (CdS); zinc selenide (ZnSe); or zinc sulfide (ZnS) can be used, for example.

A high molecular compound such as poly(2,5-pyridinediyl) (abbreviation: PPy), poly[(9,9-dihexylfluorene-2,7-diyl)-co-(pyridine-3,5-diyl)] (abbreviation: PF-Py), poly[(9,9-dioctylfluorene-2,7-diyl)-co-(2,2′-bipyridine-6,6′-diyl)] (abbreviation: PF-BPy), poly(9,9-dioctylfluorene-2,7-diyl) (abbreviation: F8), or poly[(9,9-dioctylfluorene-2,7-diyl)-alt-(benzo [2,1,3]thiadiazole-4,8-diyl)] (abbreviation: F8BT) can also be used.

A material having a condensed aromatic hydrocarbon ring such as 9-[4-(10-phenyl-9-anthryl)phenyl]-9H-carbazole (abbreviation: CzPA), 7-[4-(10-phenyl-9-anthryl)phenyl]-7H-dibenzo[c,g]carbazole (abbreviation: cgDBCzPA), 9-phenyl-3-[4-(10-phenyl-9-anthryl)phenyl]-9H-carbazole (abbreviation: PCzPA), 4- [3-(9,10-diphenyl-2-anthryl)phenyl]dibenzofuran (abbreviation: 2mDBFPPA-II), t-BuDNA, or 9-(2-naphthyl)-10-[4-(1-naphthyl)phenyl]anthracene (abbreviation: BH-1), a substance having a six-membered heteroaromatic ring including nitrogen such as bathocuproine (abbreviation: BCP), 2,9-bis(naphthalen-2-yl)-4,7-diphenyl-1,10-phenanthroline (abbreviation: NBPhen), 4,4′-di(1,10-phenanthrolin-2-yl)biphenyl (abbreviation: Phen2BP), 2,2′-(3,3′-phenylene)bis(9-phenyl- 1,10-phenanthroline) (abbreviation: mPPhen2P), 2,2′-[2,2′-bipyridine-5,6-diylbis(biphenyl-4,4′-diyl)]bisbenzoxazole (abbreviation: BOxP2BPy), 2,2′-[2-(bipyridin-2-yppyridine-5,6-diylbis(biphenyl-4,4′-diyl)]bisbenzoxazole (abbreviation: BOxP2PyPm), 1,3,5-tri[3-(3-pyridyl)phenyl]benzene (abbreviation: TmPyPB), 1,3-bis[3,5-di(pyridin-3-yl)phenyl]benzene (abbreviation: BmPyPhB), 3,3′,5,5′-tetra[(m-pyridyl)-phen-3-yl]biphenyl (abbreviation: BP4mPy), 2-(naphthalen-2-yl)-4,7-diphenyl-1,10-phenanthroline (abbreviation: HNBPhen), 3,3′,5,5′-tetra[(m-pyridyl)-phen-3-yl]biphenyl, 2,9-diphenyl-1,10-phenanthroline (abbreviation: 2,9DPPhen), or 3,4,7,8-tetramethyl-1,10-phenanthroline (abbreviation: TMePhen) can also be used.

Further, any of a variety of methods can be used for forming the layer 103 containing a light-emitting substance, regardless of whether it is a dry process or a wet process. For example, a vacuum evaporation method or a wet process (e.g., a spin coating method, a casting method, a die coating method, a blade coating method, a roll coating method, an ink-jet method, a printing method (e.g., a gravure printing method, an offset printing method, or a screen printing method), a spray coating method, a curtain coating method, or a Langmuir-Blodgett method) can be used.

Different methods may be used to form the electrodes or the layers described above.

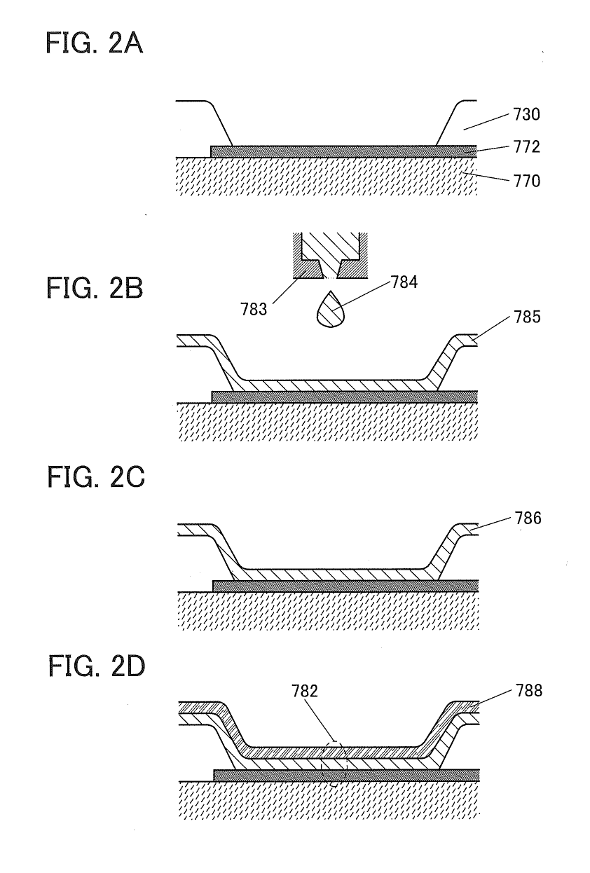

Here, a method for forming a layer 786 containing a light-emitting substance by a droplet discharge method is described with reference to FIGS. 2A to 2D. FIGS. 2A to 2D are cross-sectional views illustrating the method for forming the layer 786 containing a light-emitting substance.

First, a conductive film 772 is formed over a planarization insulating film 770, and an insulating film 730 is formed to cover part of the conductive film 772 (see FIG. 2A).

Then, a droplet 784 is discharged to an exposed portion of the conductive film 772, which is an opening of the insulating film 730, from a droplet discharge apparatus 783, so that a layer 785 containing a composition is formed. The droplet 784 is a composition containing a solvent and is attached to the conductive film 772 (see FIG. 2B).

Note that the step of discharging the droplet 784 may be performed under reduced pressure.

Next, the solvent is removed from the layer 785 containing a composition, and the resulting layer is solidified to form the layer 786 containing a light-emitting substance (see FIG. 2C).

The solvent may be removed by drying or heating.

Next, a conductive film 788 is formed over the layer 786 containing a light-emitting substance; thus, a light-emitting element 782 is completed (see FIG. 2D).

When the layer 786 containing a light-emitting substance is formed by a droplet discharge method as described above, the composition can be selectively discharged; accordingly, waste of material can be reduced. Furthermore, a lithography process or the like for shaping is not needed, and thus, the process can be simplified and cost reduction can be achieved.

The droplet discharge method described above is a general term for a means including a nozzle equipped with a composition discharge opening or a means to discharge droplets such as a head having one or a plurality of nozzles.

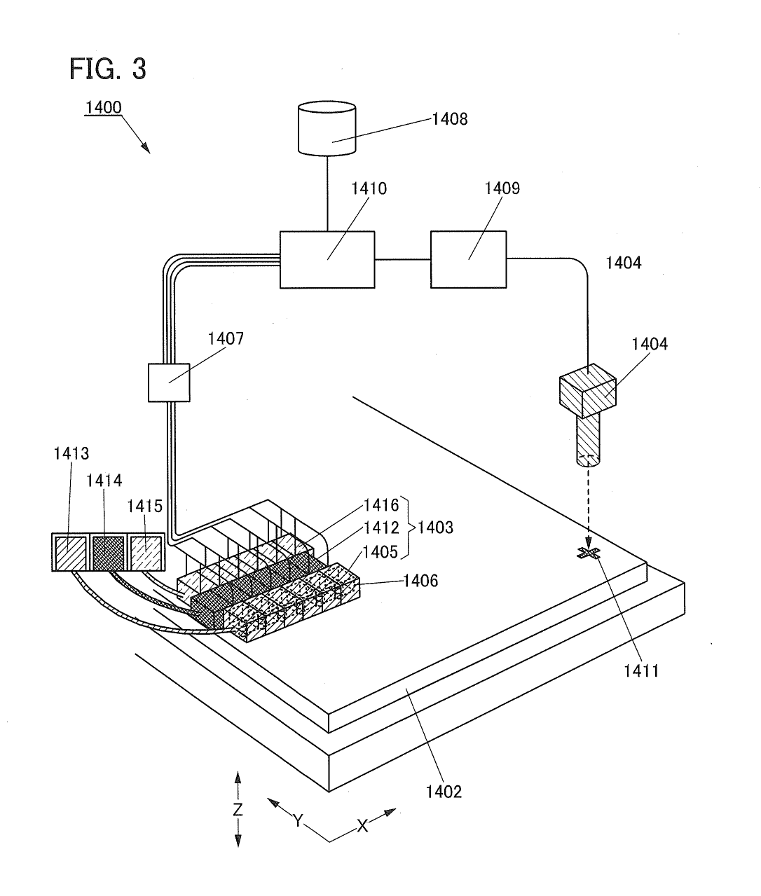

Next, a droplet discharge apparatus used for the droplet discharge method is described with reference to FIG. 3. FIG. 3 is a conceptual diagram illustrating a droplet discharge apparatus 1400.

The droplet discharge apparatus 1400 includes a droplet discharge means 1403. In addition, the droplet discharge means 1403 is equipped with a head 1405, a head 1412, and a head 1416.

The heads 1405 and 1412 are connected to a control means 1407, and this control means 1407 is controlled by a computer 1410; thus, a preprogrammed pattern can be drawn.

The drawing may be conducted at a timing, for example, based on a marker 1411 formed over a substrate 1402. Alternatively, the reference point may be determined on the basis of an outer edge of the substrate 1402. Here, the marker 1411 is detected by an imaging means 1404 and converted into a digital signal by an image processing means 1409. Then, the digital signal is recognized by the computer 1410, and then, a control signal is generated and transmitted to the control means 1407.

An image sensor or the like using a charge coupled device (CCD) or a complementary metal-oxide-semiconductor (CMOS) can be used as the imaging means 1404. Note that information about a pattern to be formed over the substrate 1402 is stored in a storage medium 1408, and a control signal is transmitted to the control means 1407 based on the information, so that each of the heads 1405, 1412, and 1416 of the droplet discharge means 1403 can be individually controlled. A material to be discharged is supplied to the heads 1405, 1412, and 1416 from material supply sources 1413, 1414, and 1415, respectively, through pipes.

Inside each of the heads 1405, 1412, and 1416, a space as indicated by a dotted line 1406 to be filled with a liquid material and a nozzle which is a discharge outlet are provided. Although it is not shown, an inside structure of the head 1412 is similar to that of the head 1405. When the nozzle sizes of the heads 1405 and 1412 are different from each other, different materials with different widths can be discharged simultaneously. Each head can discharge and draw a plurality of light-emitting materials. In the case of drawing over a large area, the same material can be simultaneously discharged to be drawn from a plurality of nozzles in order to improve throughput. When a large substrate is used, the heads 1405, 1412, and 1416 can freely scan the substrate in the directions indicated by arrows X, Y, and Z in FIG. 3, and a region in which a pattern is drawn can be freely set. Thus, a plurality of the same patterns can be drawn over one substrate.

A step of discharging the composition may be performed under reduced pressure. Also, a substrate may be heated when the composition is discharged. After discharging the composition, either drying or baking or both of them is performed. Both the drying and baking are heat treatments but different in purpose, temperature, and time period. The steps of drying and baking are performed under normal pressure or under reduced pressure by laser irradiation, rapid thermal annealing, heating using a heating furnace, or the like. Note that the timing of the heat treatment and the number of times of the heat treatment are not particularly limited. The temperature for performing each of the steps of drying and baking in a favorable manner depends on the materials of the substrate and the properties of the composition.

In the above-described manner, the layer 786 containing a light-emitting substance can be formed with the droplet discharge apparatus.

In the case where the layer 786 containing a light-emitting substance is formed with the droplet discharge apparatus, the layer 786 containing a light-emitting substance can be formed by a wet process using a composition in which a variety of organic materials or a metal-halide perovskite material are dissolved in a solvent. In that case, the following various organic solvents can be used to form a coating composition: benzene, toluene, xylene, mesitylene, tetrahydrofuran, dioxane, ethanol, methanol, n-propanol, isopropanol, n-butanol, t-butanol, acetonitrile, dimethylsulfoxide, dimethylformamide, chloroform, methylene chloride, carbon tetrachloride, ethyl acetate, hexane, cyclohexane, and the like. In particular, less polar benzene derivatives such as benzene, toluene, xylene, and mesitylene are preferable because a solution with a suitable concentration can be obtained and the material contained in ink can be prevented from deteriorating due to oxidation or the like. Furthermore, to achieve a uniform film or a film with a uniform thickness, a solvent with a boiling point of 100° C. or higher is preferably used, and further preferably, toluene, xylene, or mesitylene is used.

Note that the above-described structure can be combined as appropriate with any of the structures in this embodiment and the other embodiment.

Because of including two electron-transport layers, a light-emitting element of one embodiment of the present invention in which the metal-halide perovskite material having the above-described structure is used as a light-emitting material can improve carrier balance. Consequently, the light-emitting element can exhibit favorable light emission efficiency. Furthermore, the electron-transport layer is formed using the material which suppresses diffusion of an alkali metal or an alkaline earth metal, so that diffusion of an alkali metal or an alkaline earth metal, which adversely affects light emission of the light-emitting material, can be suppressed. Accordingly, high emission efficiency can be achieved. A light-emitting element having such a structure can efficiently produce light emission from quantum dots of the metal-halide perovskite material due to band-to-band transition, showing a significantly high external quantum efficiency exceeding 5% of the theoretical limit of an OLED that uses a fluorescent substance.

Next, an embodiment of a light-emitting element with a structure in which a plurality of light-emitting units are stacked (this type of light-emitting element is also referred to as a stacked light-emitting element) is described with reference to FIG. 1C. This light-emitting element includes a plurality of light-emitting units between an anode and a cathode. One light-emitting unit has the same structure as the layer 103 containing a light-emitting substance illustrated in FIG. 1A. In other words, the light-emitting element illustrated in FIG. 1A or FIG. 1B includes a single light-emitting unit, and the light-emitting element illustrated in FIG. 1C includes a plurality of light-emitting units.

In FIG. 1C, a first light-emitting unit 511 and a second light-emitting unit 512 are stacked between a first electrode 501 and a second electrode 502, and a charge-generation layer 513 is provided between the first light-emitting unit 511 and the second light-emitting unit 512. The first electrode 501 and the second electrode 502 correspond, respectively, to the anode 101 and the cathode 102 illustrated in FIG. 1A, and the materials given in the description for FIG. 1A can be used. Furthermore, the first light-emitting unit 511 and the second light-emitting unit 512 may have the same structure or different structures.

The charge-generation layer 513 has a function of injecting electrons into one of the light-emitting units and injecting holes into the other of the light-emitting units when a voltage is applied between the first electrode 501 and the second electrode 502. That is, in FIG. 1C, the charge-generation layer 513 injects electrons into the first light-emitting unit 511 and holes into the second light-emitting unit 512 when a voltage is applied so that the potential of the first electrode becomes higher than the potential of the second electrode.

The charge-generation layer 513 preferably has a structure similar to the structure of the charge-generation layer 116 described with reference to FIG. 1B. The composite material of an organic compound and a metal oxide has a high carrier-injection property and a high carrier-transport property; thus, low-voltage driving and low-current driving can be achieved. Note that when a surface of a light-emitting unit on the anode side is in contact with the charge-generation layer 513, the charge-generation layer 513 can also serve as a hole-injection layer of the light-emitting unit; thus, a hole-injection layer is not necessarily formed in the light-emitting unit.

In the case where the electron-injection buffer layer 119 is provided in the charge-generation layer 513, the electron-injection buffer layer serves as the electron-injection buffer layer in the light-emitting unit on the anode side and the light-emitting unit does not necessarily further need an electron-injection layer.

The light-emitting element including two light-emitting units is described with reference to FIG. 1C; however, the present invention can be similarly applied to a light-emitting element in which three or more light-emitting units are stacked. With a plurality of light-emitting units partitioned by the charge-generation layer 513 between a pair of electrodes as in the light-emitting element according to this embodiment, it is possible to provide an element which can emit light with high luminance with the current density kept low and has a long lifetime. Moreover, a light-emitting device with low power consumption, which can be driven at a low voltage, can be achieved.

When light-emitting units have different emission colors, light emission of desired color can be obtained as a whole light-emitting element.

### Embodiment 2

In this embodiment, a light-emitting device including a light-emitting element described in Embodiment 1 will be described.

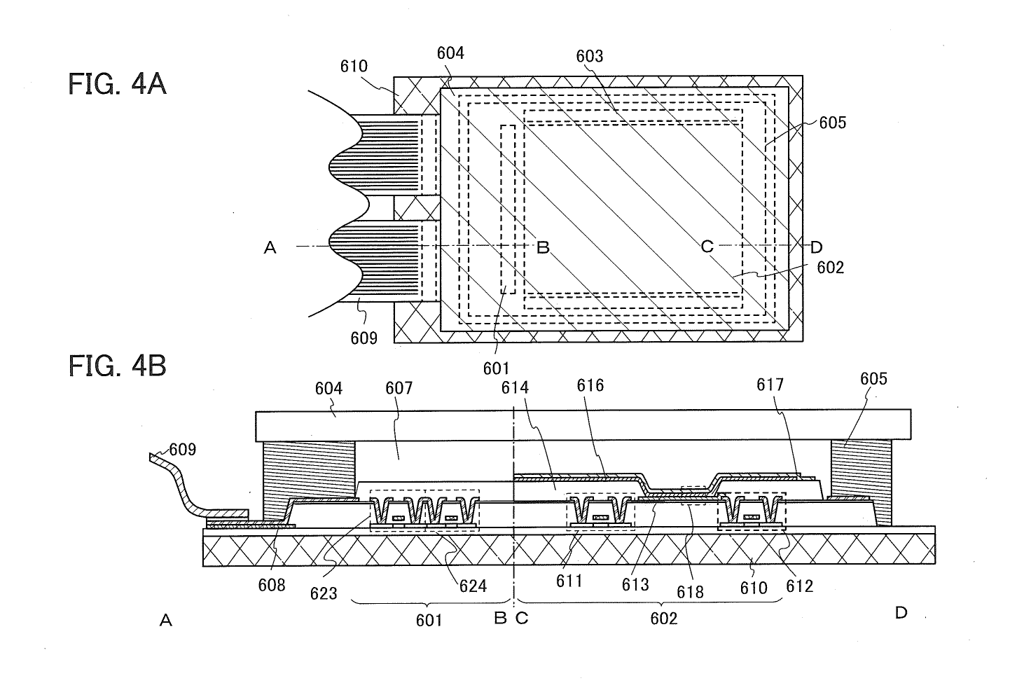

A light-emitting device of one embodiment of the present invention will be described with reference to FIGS. 4A and 4B. Note that FIG. 4A is a top view of the light-emitting device and FIG. 4B is a cross-sectional view taken along the lines A-B and C-D in FIG. 4A. The light-emitting device includes a driver circuit portion (source line driver circuit) 601, a pixel portion 602, and a driver circuit portion (gate line driver circuit) 603 which are illustrated with dotted lines. Furthermore, reference numeral 604 denotes a sealing substrate and reference numeral 605 denotes a sealant. A portion surrounded by the sealant 605 is a space 607.

Note that a lead wiring 608 is a wiring for transmitting signals to be input to the source line driver circuit 601 and the gate line driver circuit 603 and for receiving a video signal, a clock signal, a start signal, a reset signal, and the like from an FPC (flexible printed circuit) 609 functioning as an external input terminal. Although only the FPC is illustrated here, a printed wiring board (PWB) may be attached to the FPC. The light-emitting device in this specification includes, in its category, not only the light-emitting device itself but also the light-emitting device provided with the FPC or the PWB.

Next, a cross-sectional structure is described with reference to FIG. 4B. The driver circuit portion and the pixel portion are formed over an element substrate 610. Here, the source line driver circuit 601, which is the driver circuit portion, and one pixel of the pixel portion 602 are illustrated.

In the source line driver circuit 601, a CMOS circuit is formed in which an n-channel FET 623 and a p-channel FET 624 are combined. The driver circuit may be formed using various circuits such as a CMOS circuit, a PMOS circuit, or an NMOS circuit. Although a driver-integrated type where the driver circuit is formed over the substrate is described in this embodiment, a driver circuit is not necessarily formed over a substrate; a driver circuit may be fotined outside a substrate.

The pixel portion 602 includes a plurality of pixels including a switching FET 611, a current controlling FET 612, and a first electrode 613 electrically connected to a drain of the current controlling FET 612. One embodiment of the present invention is not limited to this structure. The pixel portion may include three or more FETs and a capacitor in combination.

The kind and crystallinity of a semiconductor used for the FETs is not particularly limited; an amorphous semiconductor or a crystalline semiconductor may be used. Examples of the semiconductor used for the FETs include Group 13 semiconductor, Group 14 semiconductor, compound semiconductor, oxide semiconductor, and organic semiconductor materials. Oxide semiconductors are particularly preferable. Examples of the oxide semiconductor include an In—Ga oxide and an In-M-Zn oxide (M is Al, Ga, Y, Zr, La, Ce, or Nd). Note that an oxide semiconductor material that has an energy gap of 2 eV or more, preferably 2.5 eV or more, further preferably 3 eV or more is preferably used, in which case the off-state current of the transistors can be reduced.

Note that an insulator 614 is formed so as to cover an end portion of the first electrode 613. The insulator 614 can be formed using a positive photosensitive acrylic resin film here.

In order to improve the coverage, the insulator 614 is formed to have a curved surface with curvature at its upper or lower end portion. For example, in the case where a positive photosensitive acrylic resin is used as a material of the insulator 614, only the upper end portion of the insulator 614 preferably has a curved surface with a curvature radius (0.2 μtm to 3 μm). Moreover, either a negative photosensitive resin or a positive photosensitive resin can be used as the insulator 614.

An EL layer 616 and a second electrode 617 are foiiiied over the first electrode 613. The first electrode 613, the EL layer 616, and the second electrode 617 correspond, respectively, to the anode 101, the layer 103 containing a light-emitting substance, and the cathode 102 in FIG. 1A or FIG. 1B.

The EL layer 616 preferably contains an organometallic complex. The organometallic complex is preferably used as an emission center substance in the light-emitting layer.

The sealing substrate 604 is attached using the sealant 605 to the element substrate 610; thus, a light-emitting element 618 is provided in the space 607 surrounded by the element substrate 610, the sealing substrate 604, and the sealant 605. The space 607 is filled with filler, and may be filled with an inert gas (e.g., nitrogen or argon), the sealant 605, or the like. It is preferable that the sealing substrate be provided with a recessed portion and a drying agent be provided in the recessed portion, in which case deterioration due to influence of moisture can be suppressed.

An epoxy-based resin or glass frit is preferably used for the sealant 605. A material used for them is desirably a material which does not transmit moisture or oxygen as much as possible. As the element substrate 610 and the sealing substrate 604, for example, a glass substrate, a quartz substrate, or a plastic substrate formed of fiber reinforced plastic (FRP), polyvinyl fluoride (PVF), polyester, or acrylic can be used.

Note that in this specification and the like, a transistor or a light-emitting element can be formed using any of a variety of substrates, for example. The type of a substrate is not limited to a certain type. As the substrate, a semiconductor substrate (e.g., a single crystal substrate or a silicon substrate), an SOI substrate, a glass substrate, a quartz substrate, a plastic substrate, a metal substrate, a stainless steel substrate, a substrate including stainless steel foil, a tungsten substrate, a substrate including tungsten foil, a flexible substrate, an attachment film, paper including a fibrous material, a base material film, or the like can be used, for example. As an example of a glass substrate, a barium borosilicate glass substrate, an aluminoborosilicate glass substrate, a soda lime glass substrate, or the like can be given. Examples of the flexible substrate, the attachment film, the base material film, or the like are as follows: plastic typified by polyethylene terephthalate (PET), polyethylene naphthalate (PEN), and polyether sulfone (PES). Another example is a synthetic resin such as acrylic. Alternatively, polytetrafluoroethylene (PTFE), polypropylene, polyester, polyvinyl fluoride, polyvinyl chloride, or the like can be used. Alternatively, polyamide, polyimide, aramid, epoxy, an inorganic film formed by evaporation, paper, or the like can be used. Specifically, the use of semiconductor substrates, single crystal substrates, SOI substrates, or the like enables the manufacture of small-sized transistors with a small variation in characteristics, size, shape, or the like and with high current capability. A circuit using such transistors achieves lower power consumption of the circuit or higher integration of the circuit.

Alternatively, a flexible substrate may be used as the substrate, and the transistor or the light-emitting element may be provided directly over the flexible substrate. Still alternatively, a separation layer may be provided between a substrate and the transistor or between the substrate and the light-emitting element. The separation layer can be used when part or the whole of a semiconductor device formed over the separation layer is separated from the substrate and transferred onto another substrate. In such a case, the transistor can be transferred to a substrate having low heat resistance or a flexible substrate as well. For the above separation layer, a stack including inorganic films, which are a tungsten film and a silicon oxide film, or an organic resin film of polyimide or the like formed over a substrate can be used, for example.

In other words, a transistor or a light-emitting element may be formed using one substrate, and then transferred to another substrate. Examples of the substrate to which the transistor or the light-emitting element is transferred include, in addition to the above-described substrates over which transistors can be formed, a paper substrate, a cellophane substrate, an aramid film substrate, a polyimide film substrate, a stone substrate, a wood substrate, a cloth substrate (including a natural fiber (e.g., silk, cotton, or hemp), a synthetic fiber (e.g., nylon, polyurethane, or polyester), a regenerated fiber (e.g., acetate, cupra, rayon, or regenerated polyester), or the like), a leather substrate, and a rubber substrate. When such a substrate is used, a transistor with excellent properties or a transistor with low power consumption can be formed, a device with high durability and high heat resistance can be provided, or a reduction in weight or thickness can be achieved.

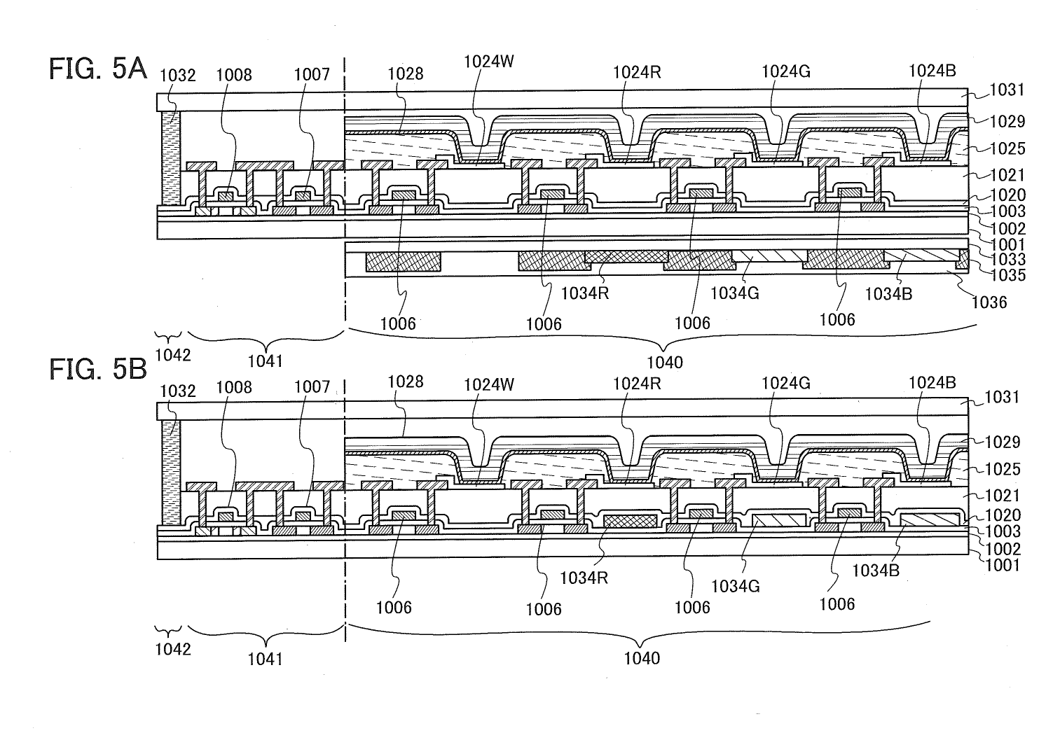

FIGS. 5A and 5B each illustrate an example of a light-emitting device in which full color display is achieved by combining a light-emitting element that exhibits white light emission with coloring layers (color filters) and the like. In FIG. 5A, a substrate 1001, a base insulating film 1002, a gate insulating film 1003, gate electrodes 1006, 1007, and 1008, a first interlayer insulating film 1020, a second interlayer insulating film 1021, a peripheral portion 1042, a pixel portion 1040, a driver circuit portion 1041, first electrodes 1024W, 1024R, 1024G, and 1024B of light-emitting elements, a partition 1025, an EL layer 1028, a cathode 1029 of the light-emitting elements, a sealing substrate 1031, a sealant 1032, and the like are illustrated.

In FIG. 5A, coloring layers (a red coloring layer 1034R, a green coloring layer 1034G, and a blue coloring layer 1034B) are provided on a transparent base material 1033. A black layer (a black matrix) 1035 may be additionally provided. The transparent base material 1033 provided with the coloring layers and the black layer is positioned and fixed to the substrate 1001. Note that the coloring layers and the black layer are covered with an overcoat layer. In FIG. 5A, light emitted from some of the light-emitting layers does not pass through the coloring layers, while light emitted from the others of the light-emitting layers passes through the coloring layers. Since light which does not pass through the coloring layers is white and light which passes through any one of the coloring layers is red, blue, or green, an image can be displayed using pixels of the four colors.

FIG. 5B illustrates an example in which the coloring layers (the red coloring layer 1034R, the green coloring layer 1034G, and the blue coloring layer 1034B) are formed between the gate insulating film 1003 and the first interlayer insulating film 1020. As in this structure, the coloring layers may be provided between the substrate 1001 and the sealing substrate 1031.

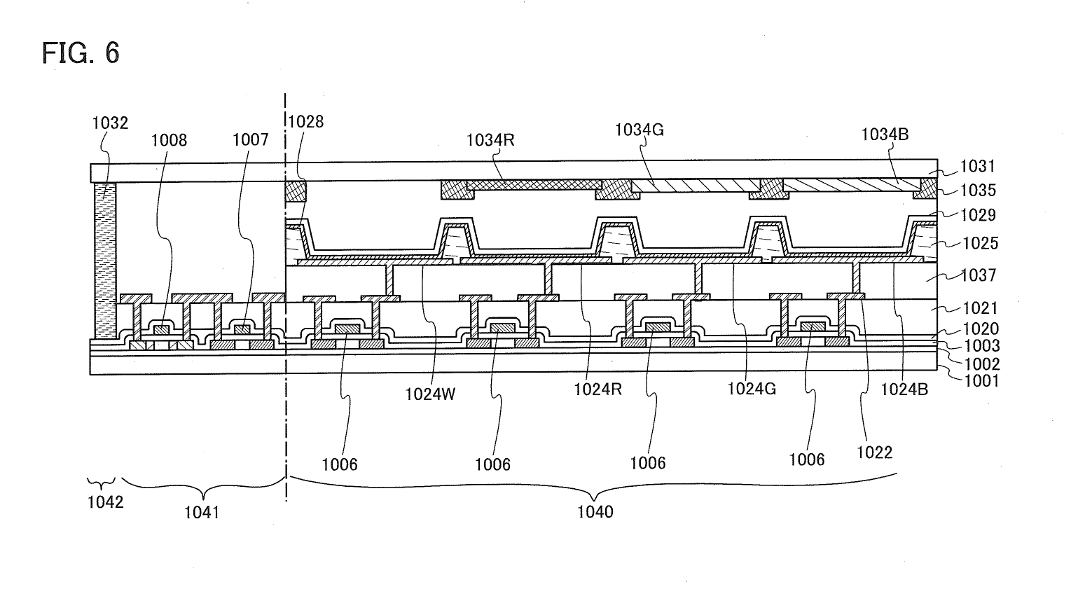

The above-described light-emitting device has a structure in which light is extracted from the substrate 1001 side where the FETs are formed (a bottom emission structure), but may have a structure in which light is extracted from the sealing substrate 1031 side (a top emission structure). FIG. 6 is a cross-sectional view of a light-emitting device having a top emission structure. In that case, a substrate which does not transmit light can be used as the substrate 1001. The process up to the step of forming of a connection electrode which connects the FET and the anode of the light-emitting element is performed in a manner similar to that of the light-emitting device having a bottom emission structure. Then, a third interlayer insulating film 1037 is formed to cover an electrode 1022. This insulating film may have a planarization function. The third interlayer insulating film 1037 can be formed using a material similar to that of the second interlayer insulating film, or can be formed using any other various materials.

The first electrodes 1024W, 1024R, 1024G, and 1024B of the light-emitting elements each function as an anode here, but may function as a cathode. Furthermore, in the case of the light-emitting device having a top emission structure as illustrated in FIG. 6, the first electrodes are preferably reflective electrodes. The EL layer 1028 is formed to have a structure similar to the structure of the layer 103 containing a light-emitting substance in FIG. 1A or FIG. 1B, with which white light emission can be obtained.

In the case of a top emission structure as illustrated in FIG. 6, sealing can be performed with the sealing substrate 1031 on which the coloring layers (the red coloring layer 1034R, the green coloring layer 1034G, and the blue coloring layer 1034B) are provided. The sealing substrate 1031 may be provided with the black layer (the black matrix) 1035 which is positioned between pixels. The coloring layers (the red coloring layer 1034R, the green coloring layer 1034G, and the blue coloring layer 1034B) and the black layer may be covered with the overcoat layer. Note that a light-transmitting substrate is used as the sealing substrate 1031.

Although an example in which full color display is performed using four colors of red, green, blue, and white is shown here, there is no particular limitation and full color display using three colors of red, green, and blue or four colors of red, green, blue, and yellow may be performed.

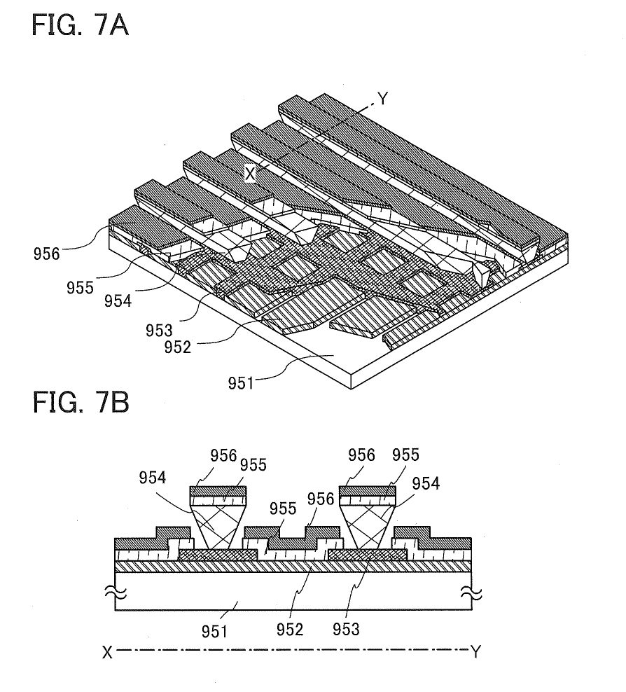

FIGS. 7A and 7B illustrate a passive matrix light-emitting device of one embodiment of the present invention. FIG. 7A is a perspective view of a light-emitting device, and FIG. 7B is a cross-sectional view taken along the line X-Y of FIG. 7A. In FIGS. 7A and 7B, an EL layer 955 is provided between an electrode 952 and an electrode 956 over a substrate 951. An end portion of the electrode 952 is covered with an insulating layer 953. A partition layer 954 is provided over the insulating layer 953. Sidewalls of the partition layer 954 are aslope such that the distance between the sidewalls is gradually narrowed toward the surface of the substrate. That is, a cross section in a short side direction of the partition layer 954 is a trapezoidal shape, and a lower side (the side facing the same direction as the plane direction of the insulating layer 953 and touching the insulating layer 953) is shorter than an upper side (the side facing the same direction as the plane direction of the insulating layer 953, and not touching the insulating layer 953). By providing the partition layer 954 in this manner, defects of the light-emitting element due to static charge and the like can be prevented.

Since many minute light-emitting elements arranged in a matrix can be controlled with the FETs formed in the pixel portion, the above-described light-emitting device can be suitably used as a display device for displaying images.

### <<Lighting Device>>

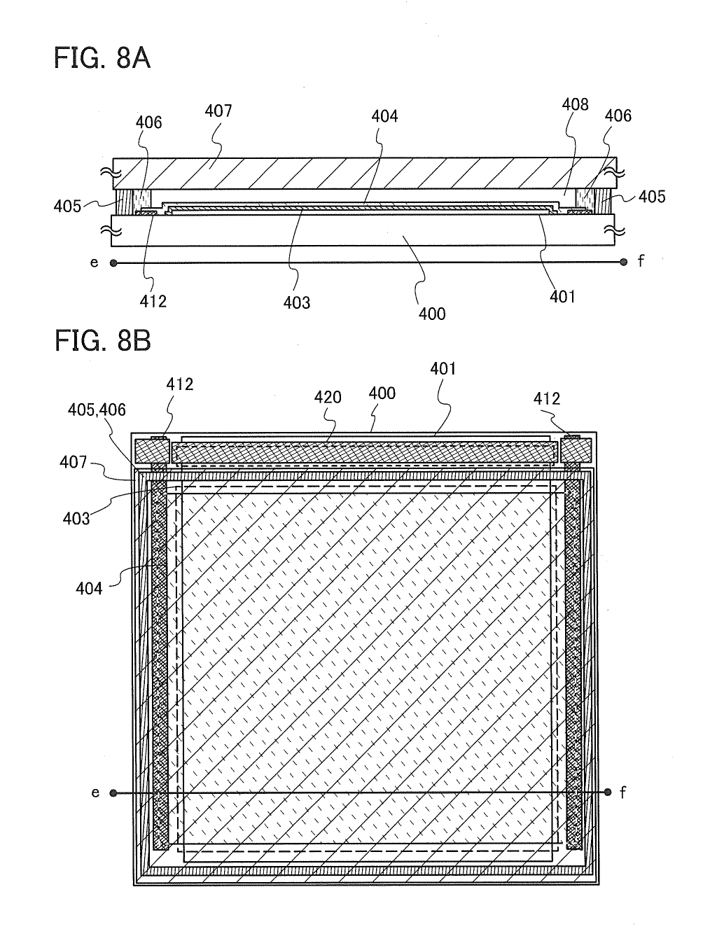

A lighting device of one embodiment of the present invention is described with reference to FIGS. 8A and 8B. FIG. 8B is a top view of the lighting device, and FIG. 8A is a cross-sectional view taken along the line e-f in FIG. 8B.

In the lighting device, a first electrode 401 is formed over a substrate 400 which is a support and has a light-transmitting property. The first electrode 401 corresponds to the anode 101 in FIGS. 1A and 1B. When light is extracted through the first electrode 401 side, the first electrode 401 is formed using a material having a light-transmitting property.

A pad 412 for applying voltage to a second electrode 404 is provided over the substrate 400.

An EL layer 403 is formed over the first electrode 401. The EL layer 403 corresponds to, for example, the layer 103 containing a light-emitting substance in FIGS. 1A and 1B. For these structures, the corresponding description can be referred to.

The second electrode 404 is formed to cover the EL layer 403. The second electrode 404 corresponds to the cathode 102 in FIG. 1A. The second electrode 404 contains a material having high reflectivity when light is extracted through the first electrode 401 side. The second electrode 404 is connected to the pad 412, whereby voltage is applied thereto.

A light-emitting element is formed with the first electrode 401, the EL layer 403, and the second electrode 404. The light-emitting element is fixed to a sealing substrate 407 with sealants 405 and 406 and sealing is performed, whereby the lighting device is completed. It is possible to use only either the sealant 405 or the sealant 406. In addition, the inner sealant 406 (not shown in FIG. 8B) can be mixed with a desiccant that enables moisture to be adsorbed, which results in improved reliability.

When part of the pad 412 and part of the first electrode 401 are extended to the outside of the sealants 405 and 406, the extended parts can function as external input terminals. An IC chip 420 mounted with a converter or the like may be provided over the external input terminals.

### <<Electronic Device>>

Examples of an electronic device of one embodiment of the present invention are described. Examples of the electronic device include a television device (also referred to as a television or a television receiver), a monitor of a computer or the like, a digital camera, a digital video camera, a digital photo frame, a mobile phone (also referred to as a mobile telephone or a mobile phone device), a portable game console, a portable information terminal, an audio reproducing device, and a large-sized game machine such as a pachinko machine. Specific examples of these electronic devices are described below.

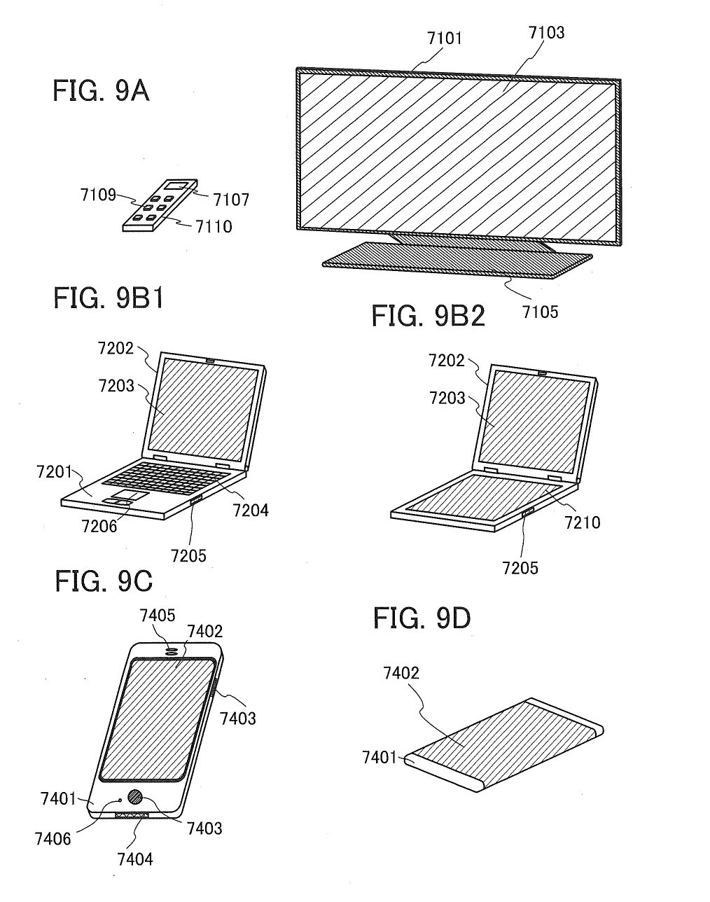

FIG. 9A illustrates an example of a television device. In the television device, a display portion 7103 is incorporated in a housing 7101. In addition, here, the housing 7101 is supported by a stand 7105. Images can be displayed on the display portion 7103, and in the display portion 7103, light-emitting elements are arranged in a matrix.

The television device can be operated with an operation switch of the housing 7101 or a separate remote controller 7110. With operation keys 7109 of the remote controller 7110, channels and volume can be controlled and images displayed on the display portion 7103 can be controlled. Furthermore, the remote controller 7110 may be provided with a display portion 7107 for displaying data output from the remote controller 7110.

Note that the television device is provided with a receiver, a modem, and the like. With the use of the receiver, a general television broadcast can be received. Moreover, when the display device is connected to a communication network with or without wires via the modem, one-way (from a sender to a receiver) or two-way (between a sender and a receiver or between receivers) information communication can be performed.

FIG. 9B1 illustrates a computer, which includes a main body 7201, a housing 7202, a display portion 7203, a keyboard 7204, an external connection port 7205, a pointing device 7206, and the like. Note that this computer is manufactured by using light-emitting elements arranged in a matrix in the display portion 7203. The computer illustrated in FIG. 9B1 may have a structure illustrated in FIG. 9B2. The computer illustrated in FIG. 9B2 is provided with a second display portion 7210 instead of the keyboard 7204 and the pointing device 7206. The second display portion 7210 is a touch panel, and input can be performed by operation of display for input on the second display portion 7210 with a finger or a dedicated pen. The second display portion 7210 can also display images other than the display for input. The display portion 7203 may also be a touch panel. Connecting the two screens with a hinge can prevent troubles; for example, the screens can be prevented from being cracked or broken while the computer is being stored or carried.

FIGS. 9C and 9D illustrate an example of a portable information terminal. The portable information terminal is provided with a display portion 7402 incorporated in a housing 7401, operation buttons 7403, an external connection port 7404, a speaker 7405, a microphone 7406, and the like. Note that the portable information terminal has the display portion 7402 including light-emitting elements arranged in a matrix.

Information can be input to the portable information terminal illustrated in FIGS. 9C and 9D by touching the display portion 7402 with a finger or the like. In that case, operations such as making a call and creating e-mail can be performed by touching the display portion 7402 with a finger or the like.

There are mainly three screen modes of the display portion 7402. The first mode is a display mode mainly for displaying images. The second mode is an input mode mainly for inputting data such as text. The third mode is a display-and-input mode in which two modes of the display mode and the input mode are combined.

For example, in the case of making a call or creating e-mail, a text input mode mainly for inputting text is selected for the display portion 7402 so that text displayed on a screen can be input. In that case, it is preferable to display a keyboard or number buttons on almost the entire screen of the display portion 7402.

When a detection device including a sensor such as a gyroscope sensor or an acceleration sensor for sensing inclination is provided inside the portable information terminal, screen display of the display portion 7402 can be automatically changed by determining the orientation of the portable information terminal (whether the portable information terminal is placed horizontally or vertically).

The screen modes are switched by touching the display portion 7402 or operating the operation buttons 7403 of the housing 7401. Alternatively, the screen modes can be switched depending on kinds of images displayed on the display portion 7402. For example, when a signal of an image displayed on the display portion is a signal of moving image data, the screen mode is switched to the display mode. When the signal is a signal of text data, the screen mode is switched to the input mode.

Moreover, in the input mode, when input by touching the display portion 7402 is not performed within a specified period while a signal sensed by an optical sensor in the display portion 7402 is sensed, the screen mode may be controlled so as to be switched from the input mode to the display mode.

The display portion 7402 may also function as an image sensor. For example, an image of a palm print, a fingerprint, or the like is taken by touch on the display portion 7402 with the palm or the finger, whereby personal authentication can be performed. Furthermore, by providing a backlight or a sensing light source which emits near-infrared light in the display portion, an image of a finger vein, a palm vein, or the like can be taken.

Note that in the above electronic devices, any of the structures described in this specification can be combined as appropriate.

The display portion preferably includes a light-emitting element of one embodiment of the present invention. The light-emitting element can have high emission efficiency. In addition, the light-emitting element can be driven with low drive voltage. Thus, the electronic device including the light-emitting element of one embodiment of the present invention can have low power consumption.

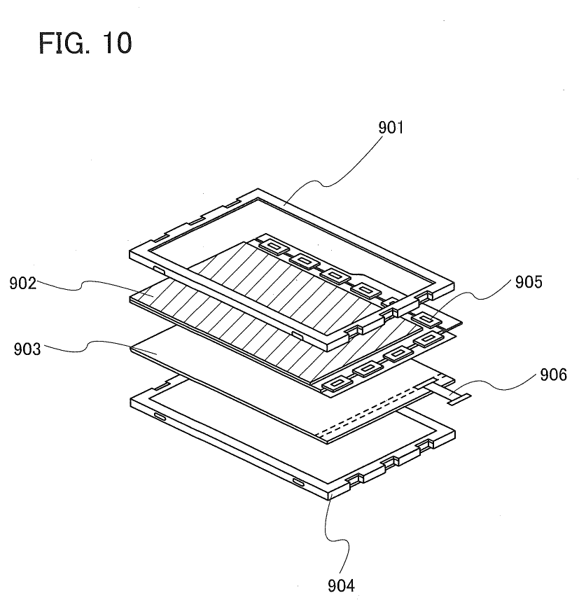

FIG. 10 illustrates an example of a liquid crystal display device including the light-emitting element for a backlight. The liquid crystal display device illustrated in FIG. 10 includes a housing 901, a liquid crystal layer 902, a backlight unit 903, and a housing 904. The liquid crystal layer 902 is connected to a driver IC 905. The light-emitting element is used for the backlight unit 903, to which current is supplied through a terminal 906.

As the light-emitting element, a light-emitting element of one embodiment of the present invention is preferably used. By including the light-emitting element, the backlight of the liquid crystal display device can have low power consumption.

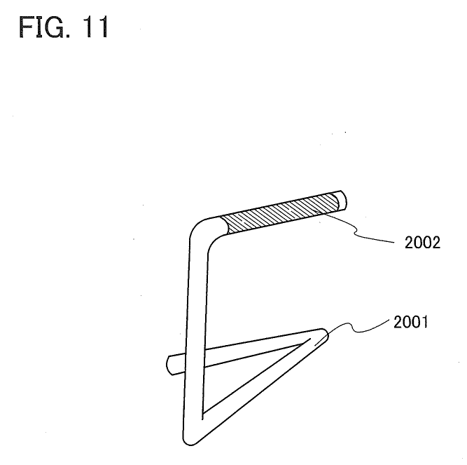

FIG. 11 illustrates an example of a desk lamp of one embodiment of the present invention. The desk lamp illustrated in FIG. 11 includes a housing 2001 and a light source 2002, and a lighting device including a light-emitting element is used as the light source 2002.

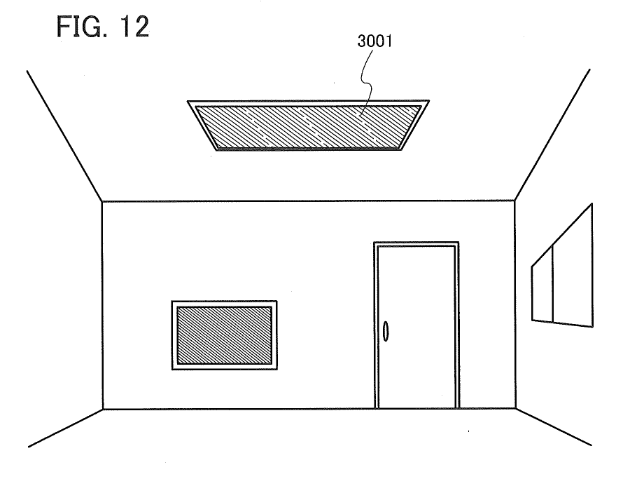

FIG. 12 illustrates an example of an indoor lighting device 3001. The light-emitting element of one embodiment of the present invention is preferably used in the lighting device 3001.

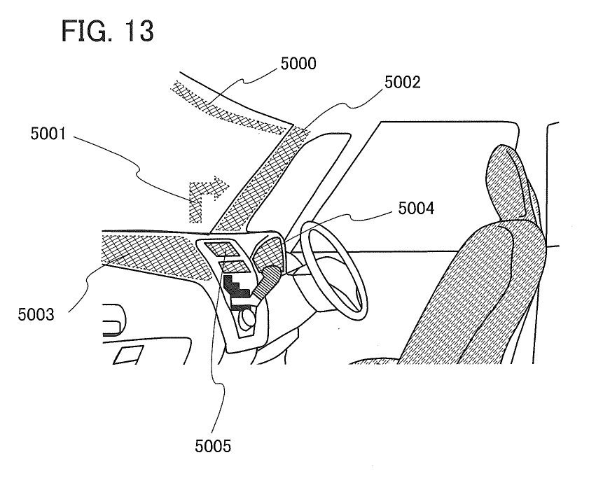

An automobile of one embodiment of the present invention is illustrated in FIG. 13. In the automobile, light-emitting elements are used for a windshield and a dashboard. Display regions 5000 to 5005 are provided by using the light-emitting elements. Display regions 5000 to 5005 are preferably formed by using the light-emitting elements of one embodiment of the present invention. This suppresses power consumption of the display regions 5000 to 5005, showing suitability for use in an automobile.

The display regions 5000 and 5001 are display devices which are provided in the automobile windshield and which include the light-emitting elements. When a first electrode and a second electrode are formed of electrodes having light-transmitting properties in these light-emitting elements, what is called a see-through display device, through which the opposite side can be seen, can be obtained. Such see-through display devices can be provided even in the windshield of the automobile, without hindering the vision. Note that in the case where a transistor for driving the light-emitting element is provided, a transistor having a light-transmitting property, such as an organic transistor using an organic semiconductor material or a transistor using an oxide semiconductor, is preferably used.

The display region 5002 is a display device which is provided in a pillar portion and which includes the light-emitting element. The display region 5002 can compensate for the view hindered by the pillar portion by showing an image taken by an imaging unit provided in the car body. Similarly, the display region 5003 provided in the dashboard can compensate for the view hindered by the car body by showing an image taken by an imaging unit provided in the outside of the car body, which leads to elimination of blind areas and enhancement of safety. Showing an image so as to compensate for the area which a driver cannot see makes it possible for the driver to confirm safety easily and comfortably.

The display region 5004 and the display region 5005 can provide a variety of kinds of information such as navigation information, a speedometer, a tachometer, a mileage, a fuel meter, a gearshift indicator, and air-condition setting. The content or layout of the display can be changed freely by a user as appropriate. Note that such information can also be shown by the display regions 5000 to 5003. The display regions 5000 to 5005 can also be used as lighting devices.

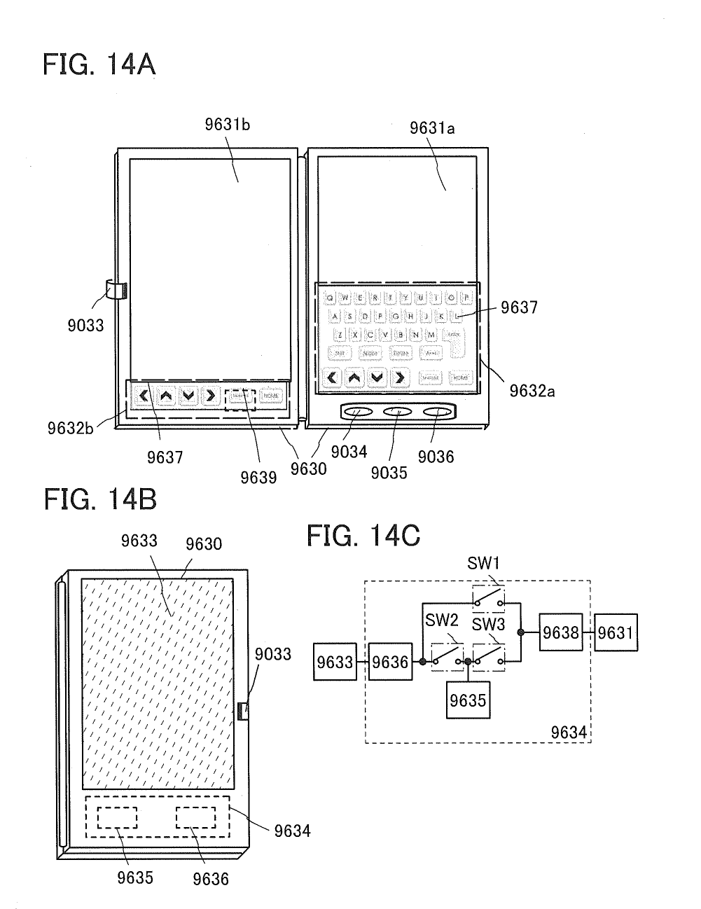

FIGS. 14A and 14B illustrate an example of a foldable tablet terminal. In FIG. 14A, the tablet terminal is opened, and includes a housing 9630, a display portion 9631a, a display portion 9631b, a switch 9034 for switching display modes, a power switch 9035, a switch 9036 for switching to power-saving mode, and a fastener 9033. Note that in the tablet terminal, one or both of the display portion 9631a and the display portion 9631b are formed using a light-emitting device which includes the light-emitting element of one embodiment of the present invention.

Part of the display portion 9631a can be a touch panel region 9632a and data can be input when a displayed operation key 9637 is touched. Although a structure in which a half region in the display portion 9631a has only a display function and the other half region has a touch panel function is illustrated as an example, the structure of the display portion 9631a is not limited thereto. The whole region in the display portion 9631a may have a touch panel function. For example, the display portion 9631a can display keyboard buttons in the whole region to be a touch panel, and the display portion 9631b can be used as a display screen.

Like the display portion 9631a, part of the display portion 9631b can be a touch panel region 9632b. When a switching button 9639 for showing/hiding a keyboard on the touch panel is touched with a finger, a stylus, or the like, the keyboard can be displayed on the display portion 9631b.

Touch input can be performed in the touch panel region 9632a and the touch panel region 9632b at the same time.

The switch 9034 for switching display modes can switch the display between portrait mode, landscape mode, and the like, and between monochrome display and color display, for example. The switch 9036 for switching to power-saving mode can control display luminance to be optimal in accordance with the amount of external light in use of the tablet terminal which is sensed by an optical sensor incorporated in the tablet terminal. Another sensing device including a sensor for sensing inclination, such as a gyroscope sensor or an acceleration sensor, may be incorporated in the tablet terminal, in addition to the optical sensor.

Note that FIG. 14A illustrates an example in which the display portion 9631a and the display portion 9631b have the same display area; however, without limitation thereon, one of the display portions may be different from the other display portion in size and display quality. For example, one display panel may be capable of higher-definition display than the other display panel.

FIG. 14B illustrates the tablet terminal which is folded. The tablet terminal in this embodiment includes the housing 9630, a solar cell 9633, a charge and discharge control circuit 9634, a battery 9635, and a DCDC converter 9636. Note that in FIG. 14B, an example in which the charge and discharge control circuit 9634 includes the battery 9635 and the DCDC converter 9636 is illustrated.

Since the tablet terminal can be folded, the housing 9630 can be closed when the tablet terminal is not used. As a result, the display portion 9631a and the display portion 9631b can be protected; thus, a tablet terminal which has excellent durability and excellent reliability in terms of long-term use can be provided.

In addition, the tablet terminal illustrated in FIGS. 14A and 14B can have a function of displaying a variety of kinds of data (e.g., a still image, a moving image, and a text image), a function of displaying a calendar, a date, the time, or the like on the display portion, a touch-input function of operating or editing the data displayed on the display portion by touch input, a function of controlling processing by a variety of kinds of software (programs), and the like.

The solar cell 9633 provided on a surface of the tablet terminal can supply power to the touch panel, the display portion, a video signal processing portion, or the like. Note that the solar cell 9633 is preferably provided on one or two surfaces of the housing 9630, in which case the battery 9635 can be charged efficiently.

The structure and the operation of the charge and discharge control circuit 9634 illustrated in FIG. 14B are described with reference to a block diagram in FIG. 14C. FIG. 14C illustrates the solar cell 9633, the battery 9635, the DCDC converter 9636, a converter 9638, switches SW1 to SW3, and the display portion 9631. The battery 9635, the DCDC converter 9636, the converter 9638, and the switches SW1 to SW3 correspond to the charge and discharge control circuit 9634 illustrated in FIG. 14B.

First, an example of the operation in the case where power is generated by the solar cell 9633 using external light is described. The voltage of power generated by the solar cell is raised or lowered by the DCDC converter 9636 so that the power has a voltage for charging the battery 9635. Then, when power charged by the solar cell 9633 is used for the operation of the display portion 9631, the switch SW1 is turned on and the voltage of the power is raised or lowered by the converter 9638 so as to be voltage needed for the display portion 9631. In addition, when display on the display portion 9631 is not performed, the switch SW1 is turned off and the switch SW2 is turned on so that charge of the battery 9635 may be performed.

Although the solar cell 9633 is described as an example of a power generation means, the power generation means is not particularly limited, and the battery 9635 may be charged by another power generation means such as a piezoelectric element or a thermoelectric conversion element (Peltier element). The battery 9635 may be charged by a non-contact power transmission module capable of performing charging by transmitting and receiving power wirelessly (without contact), or any of the other charge means used in combination, and the power generation means is not necessarily provided.

One embodiment of the present invention is not limited to the tablet terminal having the shape illustrated in FIGS. 14A to 14C as long as the display portion 9631 is included.

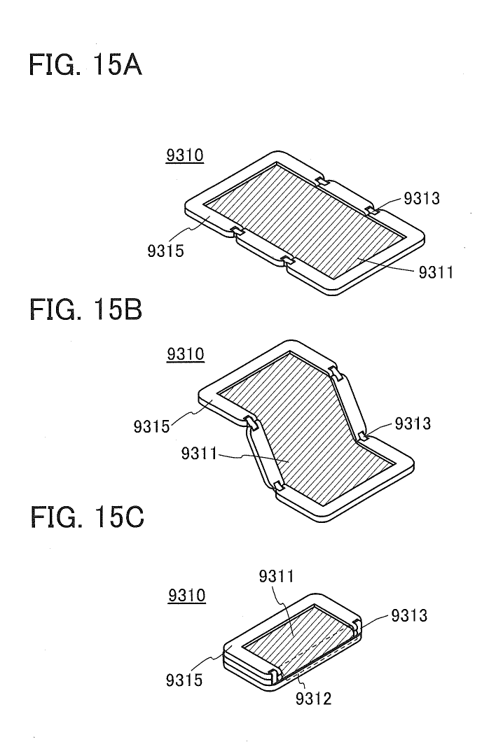

FIGS. 15A to 15C illustrate a foldable portable information terminal 9310. FIG. 15A illustrates the portable information terminal 9310 which is opened. FIG. 15B illustrates the portable information terminal 9310 which is being opened or being folded. FIG. 15C illustrates the portable information terminal 9310 which is folded. The portable information terminal 9310 is highly portable when folded. The portable information terminal 9310 is highly browsable when opened because of a seamless large display region.

A display panel 9311 is supported by three housings 9315 joined together by hinges 9313. Note that the display panel 9311 may be a touch panel (an input/output device) including a touch sensor (an input device). By bending the display panel 9311 at a connection portion between two housings 9315 with the use of the hinges 9313, the portable information terminal 9310 can be reversibly changed in shape from an opened state to a folded state. A light-emitting device of one embodiment of the present invention can be used for the display panel 9311. A display region 9312 in the display panel 9311 is a display region that is positioned at a side surface of the portable information terminal 9310 that is folded. On the display region 9312, information icons, file shortcuts of frequently used applications or programs, and the like can be displayed, and confirmation of information and start of application can be smoothly performed.

### Example 1

In this example, fabrication methods and characteristics of a light-emitting element 1 of one embodiment of the present invention and a comparative light-emitting element 1 are described in detail.

### (Method Of Fabricating Light-Emitting Element 1)

First, a film of indium tin oxide containing silicon oxide (ITSO) was formed over a glass substrate by a sputtering method, so that the anode 101 was formed. The thickness of the anode 101 was 70 nm and the electrode area was 2 mm×2 mm.

Then, in pretreatment for forming the light-emitting element over the substrate, a surface of the substrate was washed with water and baked at 200° C. for 1 hour, and then UV ozone treatment was performed for 370 seconds.

Then, the substrate was fixed to a substrate holder of a spin coater so that a surface on the anode 101 side faced upward, and an aqueous solution of poly(3,4-ethylenedioxythiophene)/poly(styrenesulfonic acid) (PEDOT/PSS) purchased from H.C. Starck (Product No. CREVIOS P VP AI 4083) was applied onto the anode 101. Then, rotation was performed at 4000 rpm for 60 seconds. The substrate was subjected to solvent removal in a chamber at a pressure of 1 Pa to 10 Pa at 130° C. for 15 minutes and then cooled down for approximately 30 minutes; thus, the hole-injection layer 111 was formed.

Then, the substrate over which the hole-injection layer 111 was formed was introduced into a glove box containing a nitrogen atmosphere. An o-dichlorobenzene solution containing 10 mg/mL of poly[N,N-bis(4-butylphenyl)-N,N′-bis(phenyl)benzidine] (abbreviation: Poly-TPD) purchased from Luminescence Technology Corp. (Product No. LT-N149) was applied onto the hole-injection layer 111. Then, rotation was performed at 4000 rpm for 60 seconds. This substrate was vacuum baked in a chamber at a pressure of 1 Pa to 10 Pa at 130° C. for 15 minutes and then cooled down for approximately 30 minutes; thus, the hole-transport layer 112 was formed.

Then, a toluene solution containing 10 mg/mL of quantum dots of the metal-halide perovskite material purchased from PlasmaChem (Product No. PL-QD-PSK-515, Lot No. AA150715d) was applied onto the hole-transport layer 112. Then, rotation was performed at 500 rpm for 60 seconds. This substrate was vacuum baked in a chamber at a pressure of 1 Pa to 10 Pa at 80° C. for 30 minutes and then cooled down for approximately 30 minutes; thus, the light-emitting layer 113 was formed.

Then, the substrate provided with the light-emitting layer 113 was put in a vacuum evaporation apparatus in which the pressure was reduced to approximately 10⁻⁴ Pa, the substrate was fixed to a substrate holder such that the side on which the light-emitting layer 113 was formed faced downward, and 2,9-bis(naphthalen-2-yl)-4,7-diphenyl-1,10-phenanthroline (abbreviation: NBPhen) was deposited to a thickness of 25 nm on the light-emitting layer 113 by an evaporation method using resistive heating, whereby the electron-transport layer 114 was formed.

Then, as the electron-injection buffer layer 115, lithium fluoride (LiF) was deposited to a thickness of 1 nm on the electron-transport layer 114 by evaporation.

Then, as the cathode 102, aluminum (Al) was formed to a thickness of 200 nm on the electron-injection buffer layer 115. Thus, the light-emitting element 1 was obtained.

### (Method of Fabricating Comparative Light-Emitting Element 1)

The comparative light-emitting element 1 was fabricated by a method similar to the method of fabricating the light-emitting element 1, except that the electron-transport layer 114 was formed using bathophenanthroline (abbreviation: BPhen) instead of NBPhen used for forming the electron-transport layer 114 of the light-emitting element 1.

Then, in a glove box containing a nitrogen atmosphere, the substrate provided with the light-emitting element and a counter glass substrate were fixed to each other using a sealant for organic EL, whereby the light-emitting element 1 was sealed. Specifically, a drying agent was attached to the counter glass substrate, the sealant was applied to the periphery of the counter glass substrate, and the counter glass substrate and the substrate over which the light-emitting element 1 was formed were bonded to each other. Then, irradiation with ultraviolet light having a wavelength of 365 nm at 6 J/cm2 and heat treatment at 80° C. for one hour were performed.

The element structures of the light-emitting element 1 and the comparative light-emitting element 1 are shown in a table below.

TABLE 1

| | Hole- | Hole- | Light- | Electron- | Electron- |
|---|---|---|---|---|---|
| | injection | transport | emitting | transport | injection |
| | layer | layer | layer | layer | layer |
| Light-emitting | PEDOT:PSS | Poly-TPD | Per-QD | NBPhen | LiF |
| element 1 | | | | (25 nm) | (1 nm) |
| Comparative | | | | BPhen | |
| light-emitting | | | | (25 nm) | |
| element 1 | | | | | |

### <Characteristics of Light-Emitting Elements>

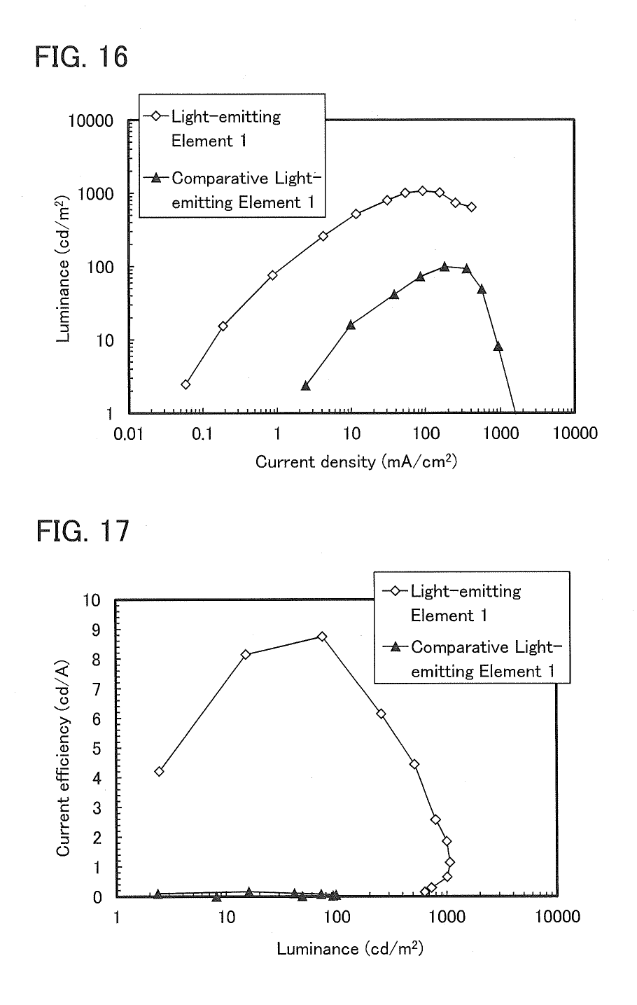

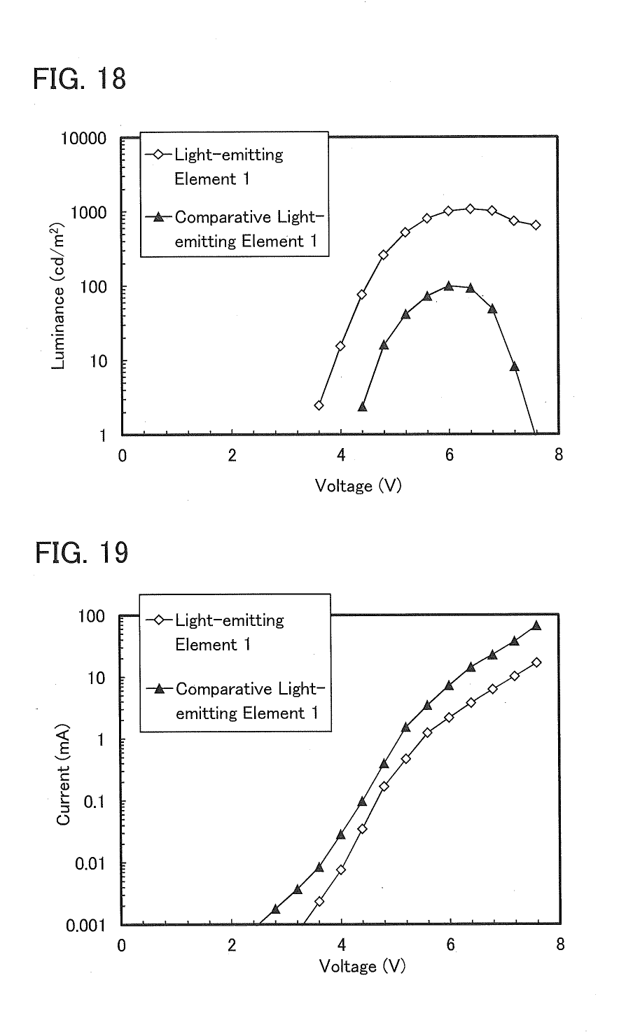

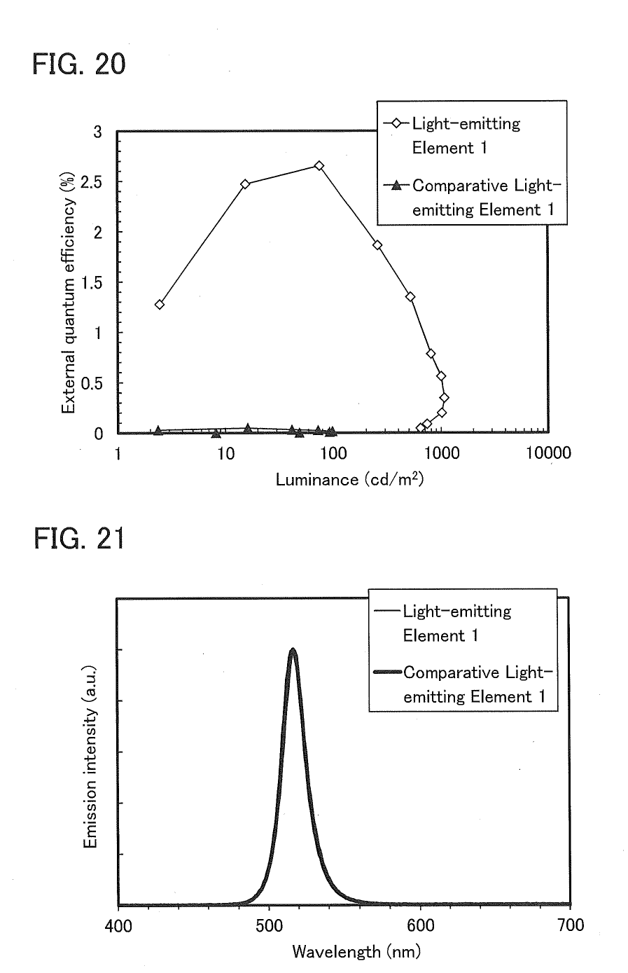

Next, the characteristics of the fabricated light-emitting element 1 and comparative light-emitting element 1 were measured. FIG. 16 shows luminance-current density characteristics of the light-emitting element 1 and the comparative light-emitting element 1. FIG. 17 shows current efficiency-luminance characteristics of the light-emitting element 1 and the comparative light-emitting element 1. FIG. 18 shows luminance-voltage characteristics of the light-emitting element 1 and the comparative light-emitting element 1. FIG. 19 shows current-voltage characteristics of the light-emitting element 1 and the comparative light-emitting element 1. FIG. 20 shows external quantum efficiency-luminance characteristics of the light-emitting element 1 and the comparative light-emitting element 1. FIG. 21 shows emission spectra of the light-emitting element 1 and the comparative light-emitting element 1.

The luminance-voltage characteristics shown in FIG. 18 are more favorable in the light-emitting element 1 than in the comparative light-emitting element 1, though current flows more easily in the comparative light-emitting element 1 than in the light-emitting element 1 as shown in FIG. 19. Furthermore, FIG. 17 and FIG. 20 show that there is an extremely large difference in the current efficiency and the external quantum efficiency between the light-emitting element 1 and the comparative light-emitting element 1. In particular, the maximum external quantum efficiency of the light-emitting element 1 is 2.7%, whereas the maximum external quantum efficiency of the comparative light-emitting element 1 is 0.049%. It is shown that the emission efficiency is increased 50 or more times by the application of the present invention.

In the electron-transport layer 114 of the comparative light-emitting element 1, BPhen represented by a structural formula (i) shown below was used. In the electron-transport layer 114 of the light-emitting element 1, NBPhen represented by a structural formula (ii) shown below was used.

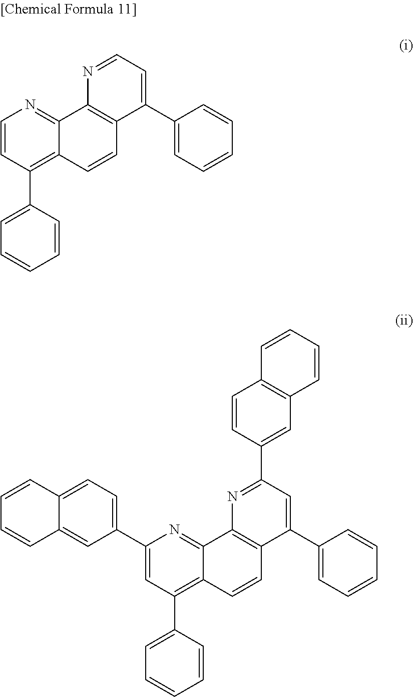 [SMILES: c1ccc(-c2ccnc3c2ccc2c(-c4ccccc4)ccnc23)cc1 ; c1ccc(-c2cc(-c3ccc4ccccc4c3)nc3c2ccc2c(-c4ccccc4)cc(-c4ccc5ccccc5c4)nc23)cc1]

BPhen and NBPhen have the same main skeleton and differ only in the presence of substituents at the 2- and 9-positions, as is seen from the above structural formulae. The only difference between the light-emitting element 1 and the comparative light-emitting element 1 is whether NBPhen or BPhen is included in the electron-transport layer 114. Thus, it is suggested that the presence of the substituents provides the above-described difference in the characteristics.

As described above, when a material including a 1,10-phenanthroline skeleton is used as the electron-transport layer and an organic-inorganic perovskite is used as a light-emitting substance in a light-emitting element, the presence of the substituents at the 2- and 9-positions of the 1,10-phenanthroline skeleton enables the light-emitting element to emit light with extremely favorable efficiency. Furthermore, it is shown that the emission efficiency of such an element is significantly increased as compared with that of an element including an electron-transport layer formed using a material including a 1,10-phenanthroline skeleton in which the 2- and 9-positions are unsubstituted.

### Example 2

In this example, fabrication methods and characteristics of a light-emitting element 2 and a light-emitting element 3 that are one embodiment of the present invention are described in detail.

### (Method of Fabricating Light-Emitting Element 2)

First, a film of indium tin oxide containing silicon oxide (ITSO) was formed over a glass substrate by a sputtering method, so that the anode 101 was formed. The thickness of the anode 101 was 70 nm and the electrode area was 2 mm×2 mm.

Then, in pretreatment for forming the light-emitting element over the substrate, a surface of the substrate was washed with water and baked at 200° C. for 1 hour, and then UV ozone treatment was performed for 370 seconds.

Then, the substrate was fixed to a substrate holder of a spin coater so that a surface on the anode 101 side faced upward, and an aqueous solution of poly(3,4-ethylenedioxythiophene)/poly(styrenesulfonic acid) (PEDOT/PSS) purchased from H.C. Starck (Product No. CREVIOS P VP AI 4083) was applied onto the anode 101. Then, rotation was performed at 4000 rpm for 60 seconds. The substrate was vacuum baked in a chamber at a pressure of 1 Pa to 10 Pa at 130° C. for 15 minutes and then cooled down for approximately 30 minutes; thus, the hole-injection layer 111 was formed.

Then, the substrate over which the hole-injection layer 111 was formed was introduced into a glove box containing a nitrogen atmosphere. An o-dichlorobenzene solution containing 10 mg/mL of poly[N-bis(4-butylphenyl)-N,N′-bis(phenyl)benzidine] (abbreviation: Poly-TPD) purchased from Luminescence Technology Corp. (Product No. LT-N149) was applied onto the hole-injection layer 111. Then, rotation was performed at 4000 rpm for 60 seconds. This substrate was vacuum baked in a chamber at a pressure of 1 Pa to 10 Pa at 130° C. for 15 minutes and then cooled down for approximately 30 minutes; thus, the hole-transport layer 112 was formed.

Then, a toluene solution containing 10 mg/mL of quantum dots of the metal-halide perovskite material purchased from PlasmaChem (Product No. PL-QD-PSK-515,Lot No. AA150715d) was applied onto the hole-transport layer 112. Then, rotation was performed at 500 rpm for 60 seconds. This substrate was vacuum baked in a chamber at a pressure of 1 Pa to 10 Pa at 80° C. for 30 minutes and then cooled down for approximately 30 minutes; thus, the light-emitting layer 113 was formed.

Then, the substrate provided with the light-emitting layer 113 was put in a vacuum evaporation apparatus in which the pressure was reduced to approximately 10₋₄ Pa, the substrate was fixed to a substrate holder such that the side on which the light-emitting layer 113 was formed faced downward, and 2,9-bis(naphthalen-2-yl)-4,7-diphenyl-1,10-phenanthroline (abbreviation: NBPhen) was deposited to a thickness of 40 nm on the light-emitting layer 113 by an evaporation method using resistive heating, whereby the electron-transport layer 114 was formed.

Then, as the electron-injection buffer layer 115, lithium fluoride (LiF) was deposited to a thickness of 1 nm on the electron-transport layer 114 by evaporation.

Then, as the cathode 102, aluminum (Al) was deposited to a thickness of 200 nm on the electron-injection buffer layer 115. Thus, the light-emitting element 2 was obtained.

### (Method of Fabricating Light-Emitting Element 3)

The light-emitting element 3 was fabricated by a method similar to the method of fabricating the light-emitting element 2, except that the electron-transport layer 114 was obtained by forming bathophenanthroline (abbreviation: BPhen) to a thickness of 25 nm and then forming NBPhen to a thickness of 15 nm.

Then, in a glove box containing a nitrogen atmosphere, the substrate provided with the light-emitting element and a counter glass substrate were fixed to each other using a sealant for organic EL, whereby the light-emitting elements 2 and 3 were sealed. Specifically, a drying agent was attached to the counter glass substrate, the sealant was applied to the periphery of the counter glass substrate, and the counter glass substrate and the substrate over which the light-emitting element 2 or the light-emitting element 3was formed were bonded to each other. Then, irradiation with ultraviolet light having a wavelength of 365 nm at 6 J/cm² and heat treatment at 80° C. for one hour were performed.

The element structures of the light-emitting elements 2 and 3 are shown in a table below.

TABLE 2

| | Hole- | Hole- | Light- | Electron- | | Electron- |
|---|---|---|---|---|---|---|
| | injection | transport | emitting | transport | | injection |
| | layer | layer | layer | layer | | layer |
| Light- | PEDOT:PSS | Poly-TPD | Per-QD | NBPhen | | LiF |
| emitting | | | | (40 nm) | | (1 nm) |
| element | | | | | | |
| 2 | | | | | | |
| Light- | | | | BPhen | NBPhen | |
| emitting | | | | (25 | (15 nm) | |
| element | | | | nm) | | |
| 3 | | | | | | |

### <Characteristics of Light-Emitting Elements>

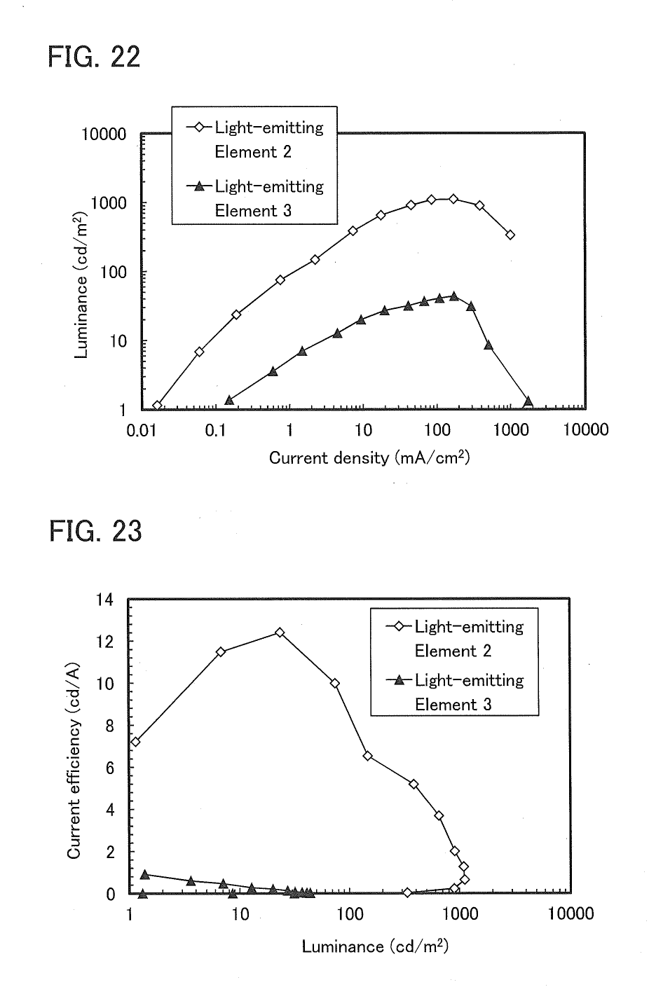

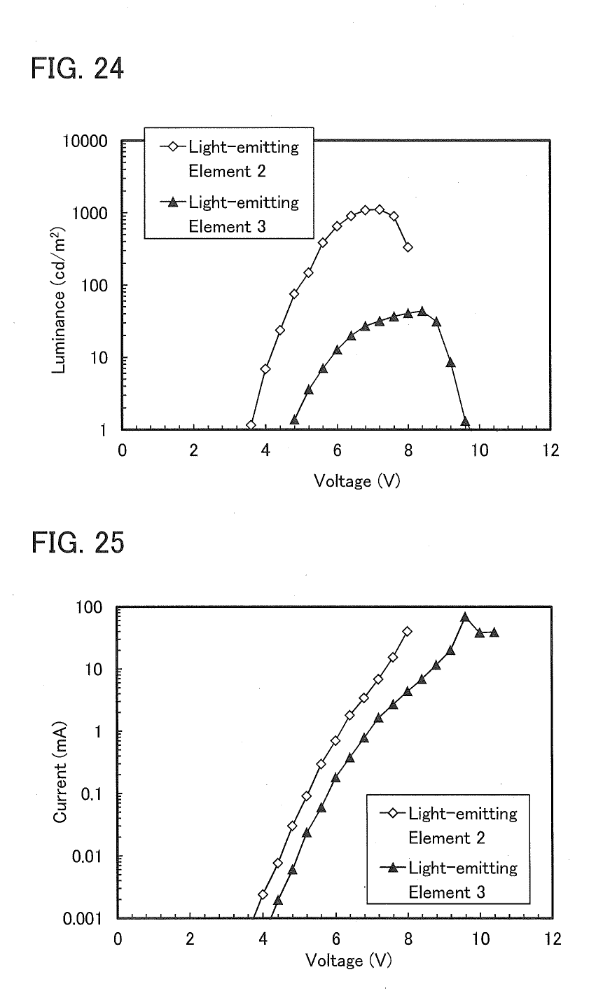

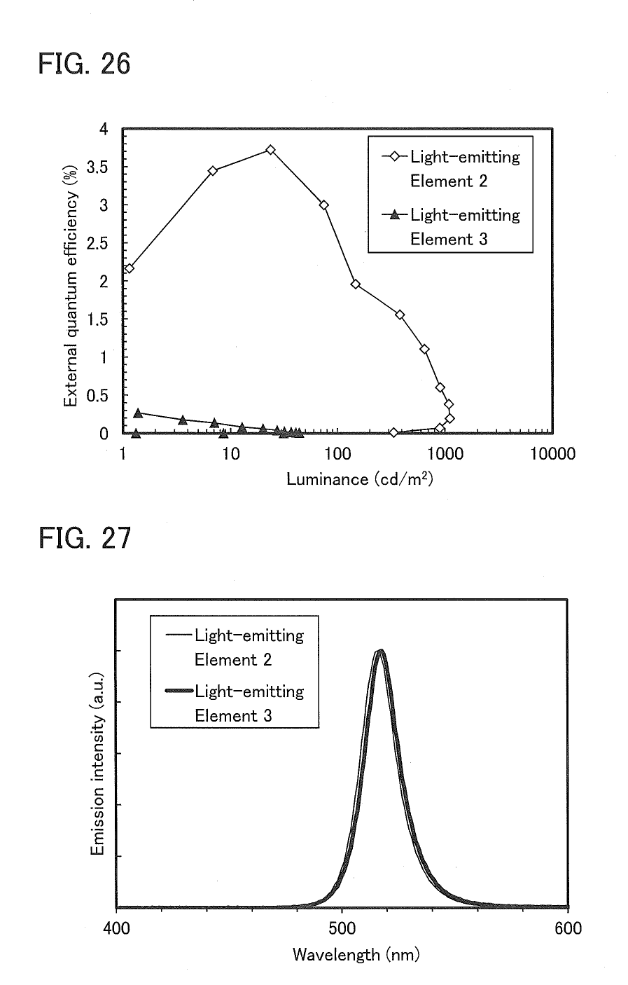

Next, the characteristics of the fabricated light-emitting elements 2 and 3 were measured. FIG. 22 shows luminance-current density characteristics of the light-emitting elements 2 and 3. FIG. 23 shows current efficiency-luminance characteristics of the light-emitting elements 2 and 3. FIG. 24 shows luminance-voltage characteristics of the light-emitting elements 2 and 3. FIG. 25 shows current-voltage characteristics of the light-emitting elements 2 and 3. FIG. 26 shows external quantum efficiency-luminance characteristics of the light-emitting elements 2 and 3. FIG. 27 shows emission spectra of the light-emitting elements 2 and 3.

FIG. 23 and FIG. 26 show that there is an extremely large difference in the current efficiency and the external quantum efficiency between the light-emitting element 2 and the light-emitting element 3. In particular, the maximum external quantum efficiency of the light-emitting element 2 is 3.7%, whereas the maximum external quantum efficiency of the light-emitting element 3 is 0.27%. It is shown that the emission efficiency of the light-emitting element 2 is increased by at least one order of magnitude compared with that of the light-emitting element 3.

The element structure of the light-emitting element 3 differs from the light-emitting element 2 only in that BPhen is substituted for the part of the electron-transport layer that is on the light-emitting layer side in the light-emitting element 2. As described in Example 1, BPhen and NBPhen have the same main skeleton and differ only in the presence of substituents at the 2- and 9-positions. Thus, it is suggested that the presence of the substituents provides the above-described difference in the characteristics.

When the light-emitting element 3 and the comparative light-emitting element 1 in Example 1 are compared with each other, the maximum external quantum efficiency of the light-emitting element 3 is five times or more as high as that of the comparative light-emitting element 1. That is, it is shown that a significant improvement in the efficiency is achieved also in the case where a part of the electron-transport layer is formed using a 1,10-phenanthroline derivative in which a 1,10-phenanthroline skeleton has substituents at the 2- and 9-positions.

As described above, when a material including a 1,10-phenanthroline skeleton is used as the electron-transport layer and an organic-inorganic perovskite is used as a light-emitting substance in a light-emitting element, the presence of the substituents at the 2- and 9-positions of the 1,10-phenanthroline skeleton enables the light-emitting element to emit light with extremely favorable efficiency.

This application is based on Japanese Patent Application Serial No. 2016-250253 filed with Japan Patent Office on Dec. 23, 2016, the entire contents of which are hereby incorporated by reference.

What is claimed is:

1. A light-emitting element comprising:
an anode;
a cathode; and
a layer including a light-emitting substance, the layer being between the anode and the cathode,
wherein the layer including the light-emitting substance includes a light-emitting layer and an electron-transport layer,
wherein the electron-transport layer is between the light-emitting layer and the cathode,
wherein the light-emitting layer includes a metal-halide perovskite material, and
wherein the electron-transport layer includes a 1,10-phenanthroline derivative including a 1,10-phenanthroline skeleton having a substituent at one of 2- and 9-positions or substituents at both of the 2- and 9-positions.

2. The light-emitting element according to claim 1, further comprising an electron-injection buffer layer between the electron-transport layer and the cathode.

3. The light-emitting element according to claim 2, wherein the electron-injection buffer layer comprises an alkali metal or an alkaline earth metal.

4. The light-emitting element according to claim 1,
wherein the substituent at one of the 2- and 9-positions and the substituents at both of the 2- and 9-positions of the 1,10-phenanthroline skeleton in the 1,10-phenanthroline derivative each independently represent an aromatic hydrocarbon group having 6 to 18 carbon atoms.

5. The light-emitting element according to claim 1,
wherein the substituent at one of the 2- and 9-positions or the substituents at both of the 2- and 9-positions of the 1,10-phenanthroline skeleton in the 1,10-phenanthroline derivative are each a naphthyl group.

6. The light-emitting element according to claim 1, wherein the 1,10-phenanthroline derivative including the 1,10-phenanthroline skeleton having the substituent at one of the 2- and 9-positions or the substituents at both of the 2- and 9-positions is 2,9-bis(naphthalen-2-yl)-4,7-diphenyl-1,10-phenanthroline.

7. The light-emitting element according to claim 1,
wherein the electron-transport layer includes a first electron-transport layer including a first substance and a second electron-transport layer including a second substance,
wherein the first electron-transport layer is between the second electron-transport layer and the light-emitting layer,
wherein the second electron-transport layer is between the first electron-transport layer and the cathode, and
wherein the second substance is the 1,10-phenanthroline derivative including the 1,10-phenanthroline skeleton having the substituent at one of the 2- and 9-positions or the substituents at both of the 2- and 9-positions.

8. The light-emitting element according to claim 1, wherein the metal-halide perovskite material is a particle including a longest part of 1 μm or less.

9. The light-emitting element according to claim 1,
wherein the metal-halide perovskite material has a layered structure where a perovskite layer and an organic layer are stacked.

10. A light-emitting element comprising:
an anode;
a cathode; and
a layer including a light-emitting substance, the layer being between the anode and the cathode,
wherein the layer including the light-emitting substance includes a light-emitting layer and an electron-transport layer, wherein the electron-transport layer is between the light-emitting layer and the cathode,
wherein the light-emitting layer includes a metal-halide perovskite material represented by a general formula (SA)MX₃, a general formula (LA)₂(SA)ₙ₋₁MₙX₃ₙ₊₁, or a general formula (PA)(SA)ₙ₋₁MₙX₃ₙ₊₁,
wherein the electron-transport layer includes a 1,10-phenanthroline derivative including a 1,10-phenanthroline skeleton having a substituent at one of 2- and 9-positions or substituents at both of the 2- and 9-positions,
wherein M represents a divalent metal ion,
wherein X represents a halogen ion,
wherein n represents an integer greater than or equal to 1 and less than or equal to 10,
wherein LA represents R¹—NH₃⁺,
wherein R¹ represents one or a plurality of an alkyl group having 2 to 20 carbon atoms, an aryl group having 6 to 20 carbon atoms, and a heteroaryl group having 4 to 20 carbon atoms,
wherein, when R¹ represents the plurality of the alkyl group having 2 to 20 carbon atoms, the aryl group having 6 to 20 carbon atoms, and the heteroaryl group having 4 to 20 carbon atoms, a plurality of groups of the same kind or different kinds is used as R¹,
wherein PA represents NH₃⁺—R²—NH₃⁺, NH₃⁺—R³—R⁴—R⁵—NH₃⁺, or a part of a polymer including an ammonium cation, and the part has a valence of +2,
wherein R² represents a single-bond alkylene group or an alkylene group having 1 to 12 carbon atoms,
wherein R³ and R⁵ each independently represent a single-bond alkylene group or alkylene group having 1 to 12 carbon atoms,
wherein R⁴ represents one or two of a cyclohexylene group and an arylene group having 6 to 14 carbon atoms,
wherein, when R⁴ represents the two of the cyclohexylene group and the arylene group having 6 to 14 carbon atoms, a plurality of groups of the same kind or different kinds is used as R⁴,
wherein SA represents a monovalent metal ion or an ammonium ion represented by R⁶—NH₃⁺, and
wherein R⁶ represents an alkyl group having 1 to 6 carbon atoms.

11. The light-emitting element according to claim 10,
wherein LA represents any of general formulae (A-1) to (A-11) and general formulae (B-1) to (B-6) 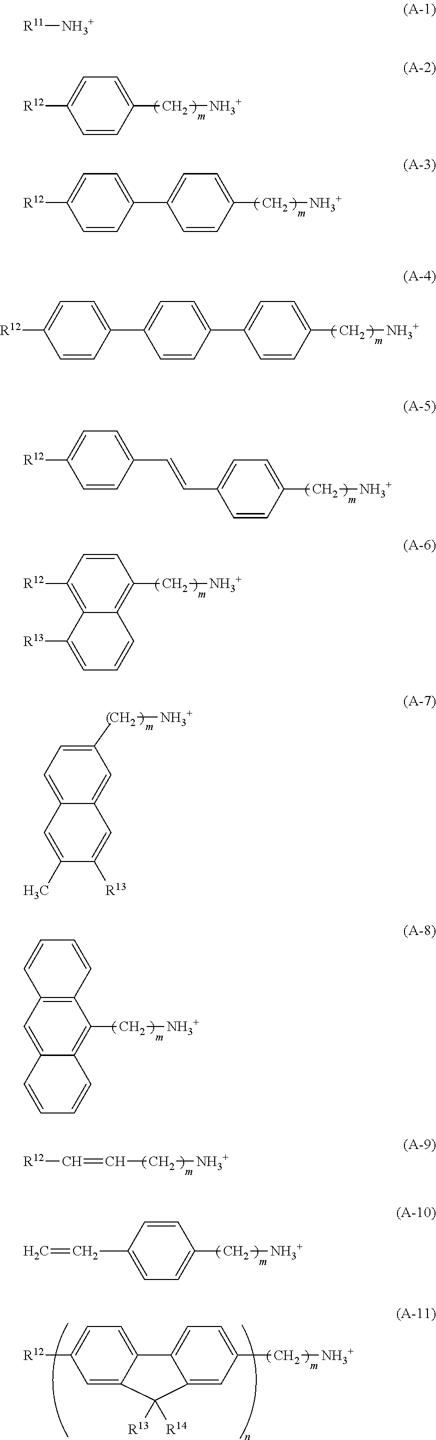 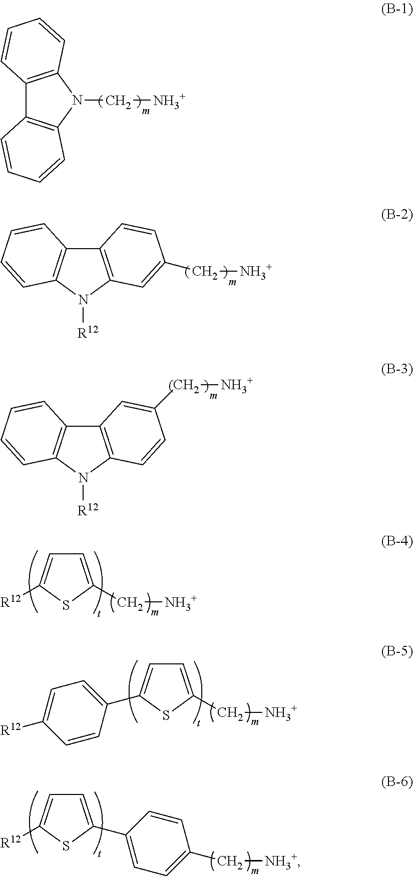
wherein PA represents any of general formulae (C-1), (C-2), and (D) and branched polyethyleneimine including ammonium cations
NH₃^{+—(CH}₂)ₘ—NH₃⁺ (C-1)
NH₃^{+—(CH}₂)ₘ⁺ (C-2) [symbol]
wherein R¹¹ represents an alkyl group having 2 to 18 carbon atoms,
wherein R¹², R¹³, and R¹⁴ represent hydrogen or an alkyl group having 1 to 18 carbon atoms,
wherein R¹⁵ represents any of structural or general formulae (R¹⁵-1) to (R¹⁵-14) 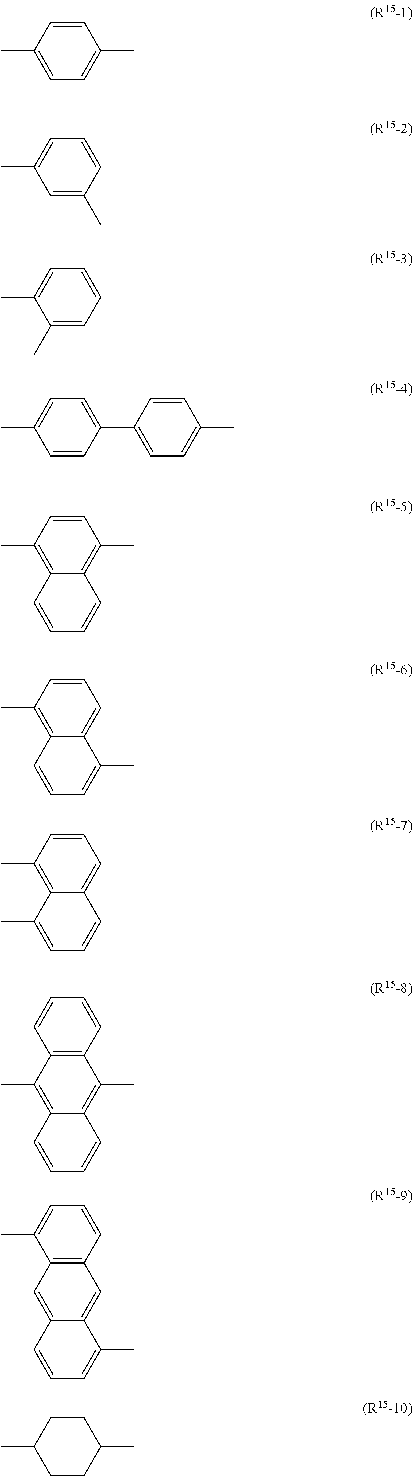 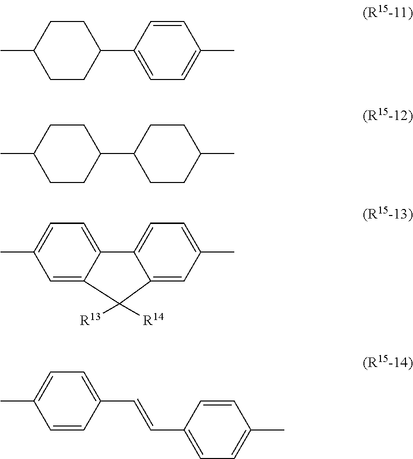
wherein R¹⁶ and R¹⁷ each independently represent hydrogen or an alkyl group having 1 to 6 carbon atoms,
wherein X represents a combination of a monomer unit A and a monomer unit B represented by any of the general formulae (D-1) to (D-6), and has a structure including the monomer unit A and the monomer unit B where the number of the monomer unit A is u and the number of the monomer unit B is v,
wherein the arrangement order of the monomer units A and B is not limited,
wherein m and l are each independently an integer of 0 to 12, and t is an integer of 1 to 18,
wherein u is an integer of 0 to 17,
wherein v is an integer of 1 to 18, and
wherein u+v is an integer of 1 to 18.

12. The light-emitting element according to claim 10, further comprising an electron-injection buffer layer between the electron-transport layer and the cathode.

13. The light-emitting element according to claim 12, wherein the electron-injection buffer layer comprises an alkali metal or an alkaline earth metal.

14. The light-emitting element according to claim 10, wherein the substituent at one of the 2- and 9-positions and the substituents at both of the 2- and 9-positions of the 1,10-phenanthroline skeleton in the 1,10-phenanthroline derivative each independently represent an aromatic hydrocarbon group having 6 to 18 carbon atoms.

15. The light-emitting element according to claim 10, wherein the substituent at one of the 2- and 9-positions or the substituents at both of the 2- and 9-positions of the 1,10-phenanthroline skeleton in the 1,10-phenanthroline derivative are each a naphthyl group.

16. The light-emitting element according to claim 10, wherein the 1,10-phenanthroline derivative including the 1,10-phenanthroline skeleton having the substituent at one of the 2- and 9-positions or the substituents at both of the 2- and 9-positions is 2,9-bis(naphthalen-2-yl)-4,7-diphenyl-1,10-phenanthroline.

17. The light-emitting element according to claim 10,
wherein the electron-transport layer includes a first electron-transport layer including a first substance and a second electron-transport layer including a second substance,
wherein the first electron-transport layer is between the second electron-transport layer and the light-emitting layer,
wherein the second electron-transport layer is between the first electron-transport layer and the cathode, and
wherein the second substance is the 1,10-phenanthroline derivative including the 1,10-phenanthroline skeleton having the substituent at one of the 2- and 9-positions or the substituents at both of the 2- and 9-positions.

18. The light-emitting element according to claim 10,
wherein the metal-halide perovskite material is a particle including a longest part of 1 μm or less.

19. The light-emitting element according to claim 10,
wherein the metal-halide perovskite material has a layered structure where a perovskite layer and an organic layer are stacked.
